(19) United States
(12) Patent Application Publication
(10) Pub. No.: US 2023/0356997 A1
(43) Pub. Date: Nov. 9, 2023

(54) PIEZOELECTRIC DRIVE ELEMENT

(71) Applicant: Panasonic Intellectual Property Management Co., Ltd., Osaka (JP)

(72) Inventors: Ryouichi TAKAYAMA, Osaka (JP); Kazuki Komaki, Osaka (JP); Takami Ishida, Osaka (JP); Kensuke Mihara, Osaka (JP)

(21) Appl. No.: 18/223,102

(22) Filed: Jul. 18, 2023

Related U.S. Application Data
(63) Continuation of application No. PCT/JP21/43297, filed on Nov. 25, 2021.

(30) Foreign Application Priority Data
Jan. 18, 2021 (JP) 2021-005767

(51) Int. Cl. B81B 3/00; G02B 26/08; G02B 26/10

(52) U.S. Cl. CPC B81B 3/0021; G02B 26/0858; G02B 26/105; B81B 2201/042; B81B 2203/058; B81B 2203/019

(57) ABSTRACT

A piezoelectric drive element includes: a movable part; a pair of piezoelectric drive parts each connected at one end portion thereof to the movable part and configured to rotate the movable part about at least a rotation axis; and a fixing part to which end portions of the piezoelectric drive parts are connected. The pair of piezoelectric drive parts are aligned in a direction along the rotation axis with the movable part located therebetween, a width of the movable part is narrower than a width of each of the pair of piezoelectric drive parts in a plan view, and the fixing part is placed in a gap region that is outside the movable part and that is located between the pair of piezoelectric drive parts in a plan view.

### CROSS REFERENCE TO RELATED APPLICATION

This application is a continuation of International Application No. PCT/JP2021/043297 filed on Nov. 25, 2021, entitled “PIEZOELECTRIC DRIVE ELEMENT”, which claims priority under 35 U.S.C. Section 119 of Japanese Patent Application No. 2021-005767 filed on Jan. 18, 2021, entitled “PIEZOELECTRIC DRIVE ELEMENT”. The disclosures of the above applications are incorporated herein by reference.

### BACKGROUND OF THE INVENTION

### Field of the Invention

The present invention relates to a piezoelectric drive element that drives a movable part by a piezoelectric actuator and that is suitable for use, for example, for the case of performing scanning with light by a mirror placed on the movable part.

### Description of Related Art

In recent years, by using micro electro mechanical system (MEMS) technology, piezoelectric drive elements that rotate a movable part have been developed. In this type of piezoelectric drive element, a mirror is placed on the movable part, thereby allowing scanning to be performed at a predetermined deflection angle with light incident on the mirror.

For example, Japanese Patent No. 6310786 describes a light deflector including: a mirror part that reflects light; a frame part that surrounds and supports the mirror part; and a pair of piezoelectric actuators that are interposed between the mirror part and the frame part and that rotate the mirror part in a reciprocating manner. The frame part is placed so as to surround both the pair of piezoelectric actuators and the mirror part which is a movable part.

When the frame part is provided so as to surround both the movable part and the pair of piezoelectric actuators as described above, a problem that the installation area of a piezoelectric drive element is increased, arises.

### SUMMARY OF THE INVENTION

A main aspect of the present invention is directed to a piezoelectric drive element. The piezoelectric drive element according to this aspect includes: a movable part; a pair of piezoelectric drive parts each connected at one end thereof to the movable part and configured to rotate the movable part about at least a rotation axis; and a fixing part to which other ends of the piezoelectric drive parts are connected. The pair of piezoelectric drive parts are aligned in a direction along the rotation axis with the movable part located therebetween, a width of the movable part is narrower than a width of each of the pair of piezoelectric drive parts in a plan view, and the fixing part is placed in a gap region that is outside the movable part and that is located between the pair of piezoelectric drive parts in a plan view.

In the piezoelectric drive element according to this aspect, the fixing part is placed in the gap region between the movable part and the pair of piezoelectric drive parts. Accordingly, the installation area of the piezoelectric drive element can be reduced.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of a piezoelectric drive element according to Embodiment 1;

FIG. 2 is a plan view schematically showing a configuration of a pair of piezoelectric drive parts according to Embodiment 1;

FIG. 3A is a cross-sectional view schematically showing a cross-section of a vibration portion according to Embodiment 1;

FIG. 3B is a cross-sectional view schematically showing a cross-section of the piezoelectric drive element according to Embodiment 1;

FIG. 4A and FIG. 4B are cross-sectional views schematically showing configurations when a pair of fixing parts according to a modification of Embodiment 1 are connected to each other on the lower side and the upper side of a rotation axis, respectively;

FIG. 5 is a plan view schematically showing a configuration of a piezoelectric drive element according to Embodiment 2;

FIG. 6 is a plan view schematically showing a configuration of a pair of piezoelectric drive parts according to Embodiment 2;

FIG. 7 is a plan view schematically showing a configuration of a piezoelectric drive element according to Modification 1 of Embodiment 2;

FIG. 8 is a plan view schematically showing a configuration of a pair of piezoelectric drive parts according to Modification 1 of Embodiment 2;

FIG. 9 is a plan view schematically showing a configuration of a piezoelectric drive element according to Modification 2 of Embodiment 2;

FIG. 10 is a plan view schematically showing a configuration of a pair of piezoelectric drive parts according to Modification 2 of Embodiment 2;

FIG. 11 is a plan view schematically showing a configuration of a piezoelectric drive element according to Embodiment 3;

FIG. 12 is a plan view schematically showing a configuration of a pair of piezoelectric drive parts according to Embodiment 3;

FIG. 13 is a plan view schematically showing a configuration of a piezoelectric drive element according to a modification of Embodiment 3;

FIG. 14 is a plan view schematically showing a configuration of a pair of piezoelectric drive parts according to the modification of Embodiment 3;

FIG. 15 is a plan view schematically showing a configuration of a piezoelectric drive element according to Embodiment 4;

FIG. 16 is a plan view schematically showing a configuration of a pair of piezoelectric drive parts according to Embodiment 4;

FIG. 17 is a plan view schematically showing a configuration of a piezoelectric drive element according to a modification of Embodiment 4;

FIG. 18 is a plan view schematically showing a configuration of a pair of piezoelectric drive parts according to the modification of Embodiment 4;

FIG. 19 is a plan view schematically showing a configuration of a piezoelectric drive element according to Embodiment 5;

FIG. 20 is a plan view schematically showing a configuration of a pair of piezoelectric drive parts according to Embodiment 5;

FIG. 21 is a cross-sectional view schematically showing a cross-section of the piezoelectric drive element according to Embodiment 5;

FIG. 22 is a cross-sectional view schematically showing a cross-section of a piezoelectric drive element according to Modification 1 of Embodiment 5;

FIG. 23 is a plan view schematically showing a configuration of a piezoelectric drive element according to Modification 2 of Embodiment 5;

FIG. 24 is a plan view schematically showing a configuration of a piezoelectric drive element according to Embodiment 6;

FIG. 25 is a plan view schematically showing a configuration of a pair of piezoelectric drive parts according to Embodiment 6;

FIG. 26 is a cross-sectional view schematically showing a cross-section of the piezoelectric drive element according to Embodiment 6;

FIG. 27 is a cross-sectional view schematically showing a cross-section of a piezoelectric drive element according to Modification 1 of Embodiment 6;

FIG. 28 is a plan view schematically showing a configuration of a piezoelectric drive element according to Modification 2 of Embodiment 6;

FIG. 29 is a plan view schematically showing a configuration of a piezoelectric drive element according to another modification; and

FIG. 30 is a plan view schematically showing a configuration of a pair of piezoelectric drive parts according to the other modification.

It should be noted that the drawings are solely for description and do not limit the scope of the present invention by any degree.

### DETAILED DESCRIPTION

In the following embodiments, each piezoelectric drive element 1 is an element for rotating a mirror around a rotation axis R10, reflecting light incident on the mirror, and scanning a target region. This type of piezoelectric drive element is sometimes also referred to as light deflector or mirror actuator. The piezoelectric drive element is not limited to one for rotating the mirror, but may rotate a member or a film other than the mirror. The following embodiments are each one embodiment of the present invention, and the present invention is not limited to the following embodiments in any way.

Hereinafter, embodiments of the present invention will be described with reference to the drawings. For convenience, in each drawing, X, Y, and Z axes that are orthogonal to each other are additionally shown, and the Z-axis positive direction is the vertical upward direction with respect to the surface of the drawing sheet.

### Embodiment 1

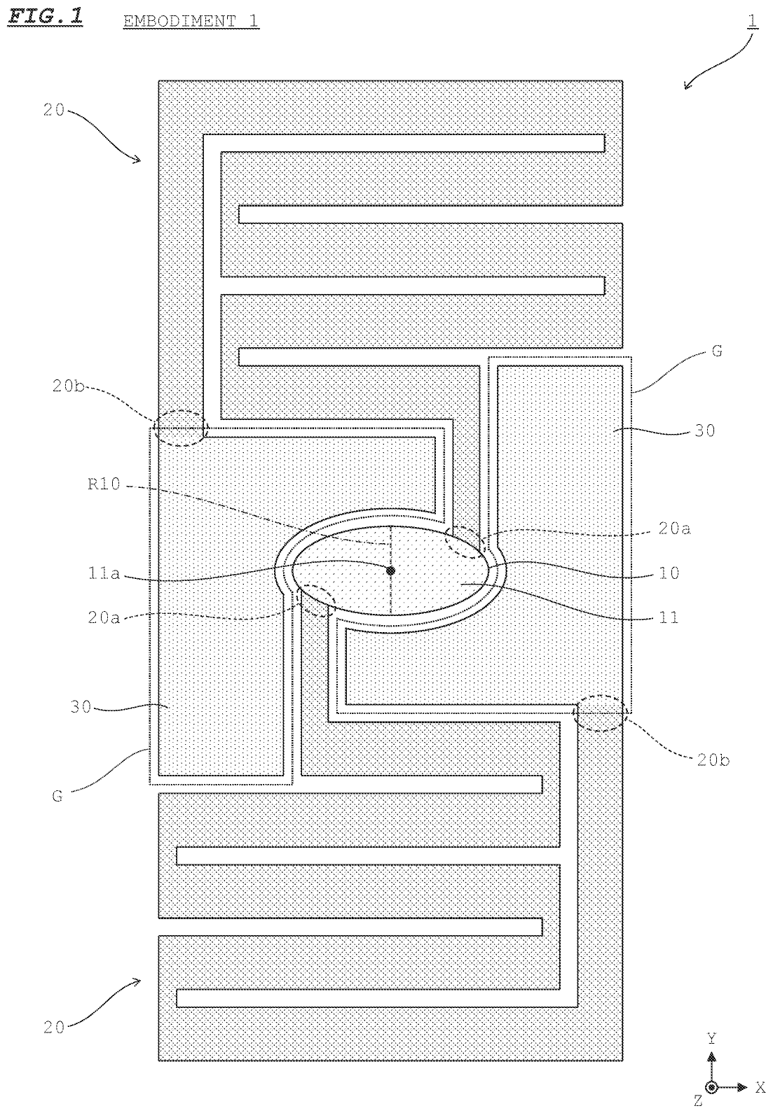

FIG. 1 is a plan view schematically showing a configuration of the piezoelectric drive element 1.

The piezoelectric drive element 1 includes a movable part 10, a pair of piezoelectric drive parts 20, and a pair of fixing parts 30. In FIG. 1, for convenience, three configurations of the movable part 10, the pair of piezoelectric drive parts 20, and the pair of fixing parts 30 are hatched differently such that the regions thereof are recognized. In the following embodiments and modifications, the same hatching is also applied in a plan view of the piezoelectric drive element 1.

The movable part 10 has a plate shape and an elliptical shape. In a plan view, the width in the X-axis direction of the movable part 10 is narrower than the width in the X-axis direction of each of the pair of piezoelectric drive parts 20. A mirror 11 is placed on the upper surface of the movable part 10. The mirror 11 is an optical reflection film formed on the upper surface of the movable part 10. The mirror 11 is composed of, for example, a dielectric multilayer film, a metal film, or the like. Light incident on the mirror 11 is reflected by the mirror 11.

The pair of piezoelectric drive parts 20 are placed and configured so as to be point-symmetrical with respect to a center 11a of the mirror 11 in a plan view. The pair of piezoelectric drive parts 20 rotate the movable part 10 about the rotation axis R10. The rotation axis R10 is an axis that passes through the center 11a and that is parallel to the Y-axis direction.

The pair of piezoelectric drive parts 20 are aligned in a direction along the rotation axis R10 with the movable part 10 located therebetween. One piezoelectric drive part 20 is placed on the Y-axis positive side of the movable part 10, and the other piezoelectric drive part 20 is placed on the Y-axis negative side of the movable part 10. End portions 20a of the pair of piezoelectric drive parts 20 are connected to the movable part 10, and other end portions 20b thereof are connected to the pair of fixing parts 30, respectively.

In the configuration in FIG. 1, in a plan view, the end portions 20a of the pair of piezoelectric drive parts 20 are connected to the movable part 10 at positions displaced relative to the rotation axis R10 in opposite directions by the same distance. However, the connection positions of the end portions 20a of the pair of piezoelectric drive parts 20 are not limited thereto, and each end portion 20a may be connected to the movable part 10, for example, at a position on the rotation axis R10.

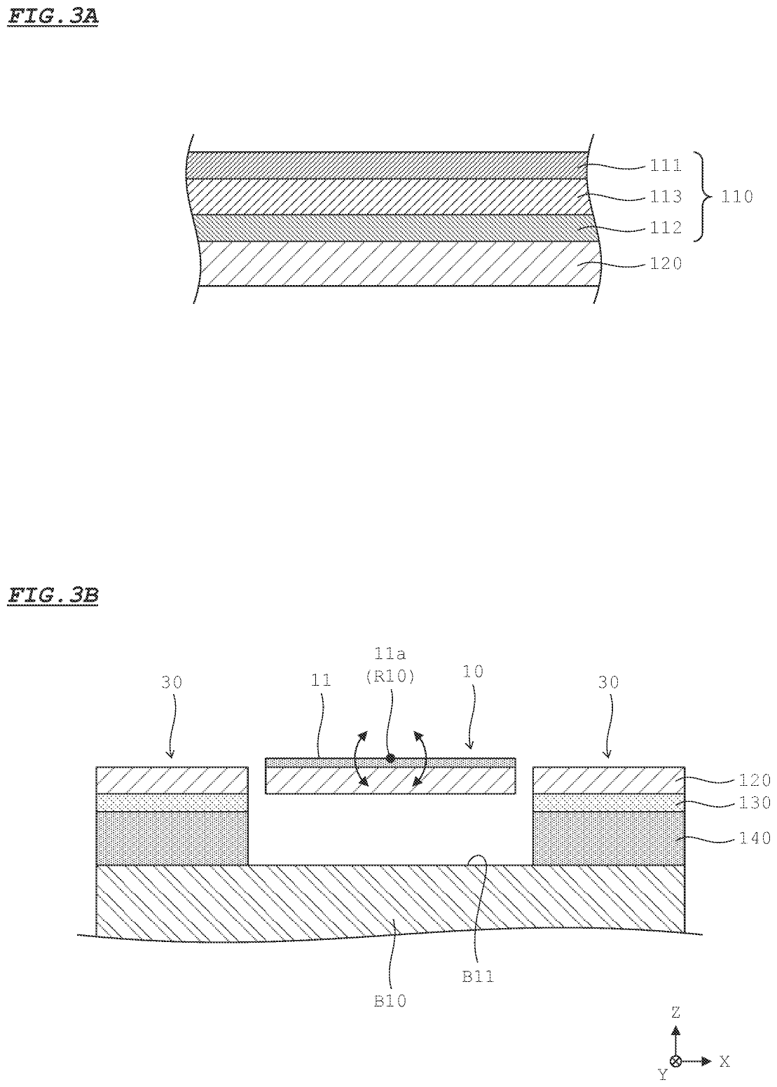

The lower surfaces of the pair of fixing parts 30 are each a flat surface, and are installed on an installation surface B11 of a base member B10 (see FIG. 3B). In a plan view, a gap region G is formed on each of the X-axis positive side and the X-axis negative side of the rotation axis R10. The gap region G is a region that is outside the movable part 10 and that is located between the pair of piezoelectric drive parts 20 in a plan view. The pair of fixing parts 30 are placed in these gap regions G, respectively, in a plan view.

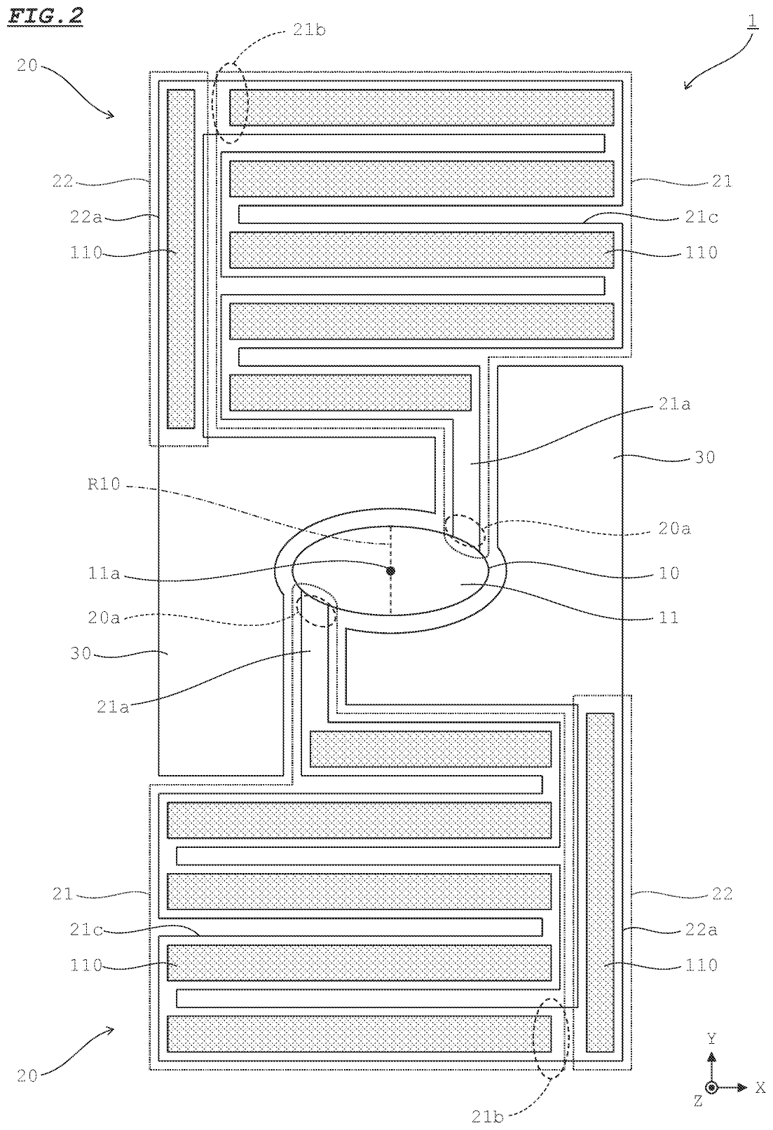

FIG. 2 is a plan view schematically showing the configuration of the pair of piezoelectric drive parts 20.

Each piezoelectric drive part 20 includes a first drive portion 21 and a second drive portion 22. The first drive portion 21 includes a coupling portion 21a, and is connected to the movable part 10 via the coupling portion 21a. An end portion of the coupling portion 21a connected to the movable part 10 forms the end portion 20a shown also in FIG. 1. The second drive portion 22 is interposed between the first drive portion 21 and the fixing part 30, and connects an end portion 21b, opposite to the end portion 20a, of the first drive portion 21 and the fixing part 30. The first drive portion 21 on the Y-axis positive side and the first drive portion 21 on the Y-axis negative side are placed at positions that are point-symmetrical with respect to the movable part 10, and the second drive portion 22 on the Y-axis positive side and the second drive portion 22 on the Y-axis negative side are placed at positions that are point-symmetrical with respect to the movable part 10.

In a plan view, one second drive portion 22 extends in one direction parallel to the rotation axis R10 from one fixing part 30 at one edge in the width direction (X-axis direction) of the piezoelectric drive element 1, and the other second drive portion 22 extends in another direction parallel to the rotation axis R10 from the other fixing part 30 at the other edge in the width direction (X-axis direction) of the piezoelectric drive element 1. In addition, in a plan view, one first drive portion 21 is placed in a range from the one second drive portion 22 to the edge on the opposite side in the width direction (X-axis direction) of the piezoelectric drive element 1, and the other first drive portion 21 is placed in a range from the other second drive portion 22 to the edge on the opposite side in the width direction (X-axis direction) of the piezoelectric drive element 1.

In a plan view, the pair of fixing parts 30 are placed in the left and right gap regions G such that the contour of the piezoelectric drive element 1 has a quadrangular shape (here, a rectangular shape). Here, the pair of fixing parts 30 are placed so as to extend over the entire gap regions G with at least an acceptable minimum gap with respect to the pair of piezoelectric drive parts 20 and the movable part 10, that is, with a minimum gap that allows the pair of piezoelectric drive parts 20 and the movable part 10 to be stably moved.

Each first drive portion 21 rotates the movable part 10 about the rotation axis R10. The first drive portion 21 includes a so-called meander-type piezoelectric actuator. That is, the first drive portion 21 includes a plurality of vibration portions 21c coupled to each other so as to form a meander shape. Each vibration portion 21c has a piezoelectric actuator 110 on an upper surface (surface on the Z-axis positive side) thereof. A wire which is not shown is connected to the piezoelectric actuator 110. When a voltage is applied to each piezoelectric actuator 110 of the first drive portion 21, a piezoelectric body 113 (see FIG. 3A) in the piezoelectric actuator 110 expands and contracts, and the first drive portion 21 bends in the Z-axis direction.

A voltage is applied to each of the piezoelectric actuators 110 of the pair of first drive portions 21 such that the pair of first drive portions 21 repeatedly oscillate in a direction parallel to the X-Z plane in the same cycle. Accordingly, the movable part 10 and the mirror 11 repeatedly rotate about the rotation axis R10.

Each second drive portion 22 extends parallel to the Y axis. The second drive portion 22 is connected at one end portion thereof to the fixing part 30, and is connected at another end portion thereof to the end portion 21b of the first drive portion 21. The second drive portion 22 includes one vibration portion 22a. As in the first drive portion 21, the vibration portion 22a of the second drive portion 22 also has a piezoelectric actuator 110 on an upper surface (surface on the Z-axis positive side) thereof. When a voltage is applied to the piezoelectric actuator 110 of the second drive portion 22, a piezoelectric body 113 (see FIG. 3A) in the piezoelectric actuator 110 expands and contracts, and the second drive portion 22 bends in the Z-axis direction.

A voltage is applied to each of the piezoelectric actuators 110 of the pair of second drive portions 22 such that the pair of second drive portions 22 repeatedly drive the end portions 21b of the pair of first drive portions 21 in the Z-axis direction in opposite phases. At this time, the drive of each second drive portion 22 is controlled such that the drive of the end portions 21b by the pair of second drive portions 22 and the drive of the end portions 21b by the pair of first drive portions 21 are synchronized in opposite phases. Accordingly, the driving force by each first drive portion 21 is increased, so that the rotational width of the movable part 10 and the mirror 11 can be widened.

FIG. 3A is a cross-sectional view schematically showing a cross-section of the vibration portion 21c or 22a obtained by cutting the vibration portion 21c or 22a along a plane perpendicular to the X-Y plane.

The vibration portions 21c and 22a each have a configuration in which the piezoelectric actuator 110 and a device layer 120 are stacked. The device layer 120 is formed from a material that is the same as that of a part of the fixing parts 30, and the piezoelectric actuator 110 is formed on the upper surface of the device layer 120. The device layer 120 is composed of Si. The piezoelectric actuator 110 is configured by stacking an upper electrode 111, a lower electrode 112, and the piezoelectric body 113. The piezoelectric body 113 is interposed between the upper electrode 111 and the lower electrode 112. The upper electrode 111 and the lower electrode 112 are each composed of a conductive film such as metal. The piezoelectric body 113 is composed of lead zirconate titanate (PZT), for example.

Each part of the vibration portion shown in FIG. 3A is placed by a semiconductor formation process, whereby the first drive portion 21 and the second drive portion 22 shown in FIG. 2 are formed, and the pair of piezoelectric drive parts 20 shown in FIG. 1 are formed.

FIG. 3B is a cross-sectional view schematically showing a configuration when a cross-section of the piezoelectric drive element 1 obtained by cutting the piezoelectric drive element 1 along a plane that passes through the center 11a of the mirror 11 and that is parallel to the X-Z plane is viewed in the Y-axis positive direction.

The rotation axis R10 extends in the Y-axis direction through the center 11a of the mirror 11, and the movable part 10 and the mirror 11 rotate about the rotation axis R10. The pair of fixing parts 30 are placed on the X-axis positive side and the X-axis negative side of the movable part 10, respectively, with gaps between the movable part 10 and the fixing parts 30. Each fixing part 30 has a configuration in which a device layer 120, a thermal oxide film 130, and a base layer 140 are stacked. The thickness of the movable part 10 is substantially equal to the thickness of the device layer 120 in FIG. 3A, and the thickness of the fixing part 30 is larger than the thickness of the movable part 10. In addition, the lower surfaces of the pair of fixing parts 30 are installed on the installation surface B11 of the base member B10 placed below the pair of fixing parts 30. The base member B10 is, for example, a member in an apparatus in which the piezoelectric drive element 1 is installed.

The piezoelectric drive element 1 is fixed to the base member B10 by installing the pair of fixing parts 30 on the installation surface B11 of the base member B10.

The pair of fixing parts 30 may be connected to each other on the lower side or the upper side of the rotation axis R10.

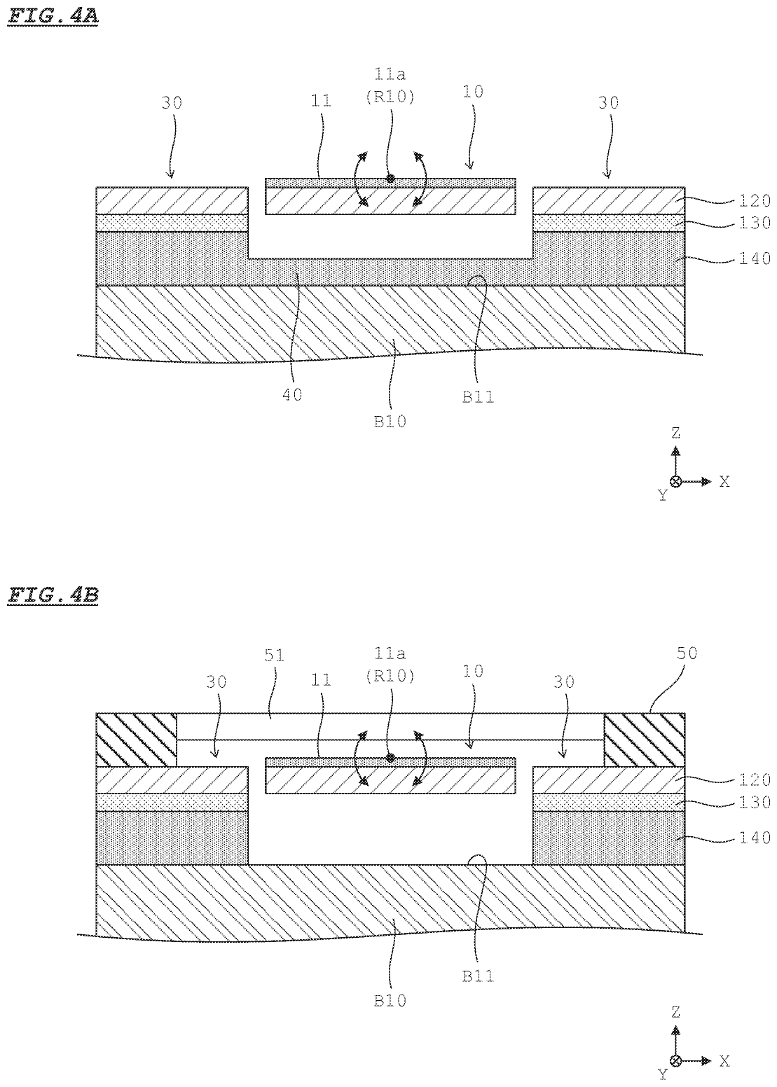

FIG. 4A and FIG. 4B are cross-sectional views schematically showing configurations when the pair of fixing parts 30 are connected to each other on the lower side and the upper side of the rotation axis R10, respectively.

In the configuration shown in FIG. 4A, a connection part 40 is formed from a material that is the same as the material forming a part of the pair of fixing parts 30, and is integrally formed with the pair of fixing parts 30. The pair of fixing parts 30 are connected to each other below the rotation axis R10 by the connection part 40. In this case as well, the lower surfaces of the fixing parts 30 are installed on the installation surface B11 of the base member B10. The connection part 40 may be made of another material different from that of the fixing parts 30.

In the configuration shown in FIG. 4B, a connection member 50 is installed on the upper surfaces of the pair of fixing parts 30. The connection member 50 is shaped to cover the upper side (Z-axis positive side) of the mirror 11, and two end portions in the X-axis direction of the connection member 50 are installed on the upper surfaces of the pair of fixing parts 30. In this case, a portion of the connection member 50 that covers the mirror 11 has a hole 51 formed so as to penetrate the connection member 50 in the Z-axis direction. Accordingly, light incident from the outside through the hole 51 is reflected by the mirror 11, and the light reflected by the mirror 11 is guided to the outside through the hole 51. As in FIG. 3B, the pair of fixing parts 30 are installed on the installation surface B11 of the base member B10. The connection member 50 is not limited to being made of a material different from that of the fixing parts 30, may be formed from a material that is the same as the material forming a part of the pair of fixing parts 30, and may be integrally formed with the pair of fixing parts 30.

### Effects of Embodiment 1

According to Embodiment 1, the following effects are achieved.

As shown in FIG. 1, the pair of piezoelectric drive parts 20 are aligned in the direction along the rotation axis R10 with the movable part 10 located therebetween. In a plan view, the width (width in the X-axis direction) of the movable part 10 is narrower than the width (width in the X-axis direction) of each of the pair of piezoelectric drive parts 20, and each fixing part 30 is placed in the gap region G, which is outside the movable part 10 and which is located between the pair of piezoelectric drive parts 20, in a plan view. Since each fixing part 30 is placed in the gap region G as described above, the installation area on the X-Y plane of the piezoelectric drive element 1 can be reduced.

As shown in FIG. 1, the fixing parts 30 are placed in the gap regions G on both sides (the X-axis positive side and the X-axis negative side) of the rotation axis R10, respectively, in a plan view. According to this configuration, the pair of piezoelectric drive parts 20 and the movable part 10 can be more stably supported by the fixing parts 30.

As shown in FIG. 2, the pair of piezoelectric drive parts 20 each include the first drive portion 21 which rotates the movable part 10 about the rotation axis R10 and the second drive portion 22 which drives the end portion 21b of the first drive portion 21 up and down (in the Z-axis direction). According to this configuration, the rotational width of the movable part 10 can be widened by controlling the drive of the second drive portion 22 as described above.

One second drive portion 22 of one piezoelectric drive part 20 and one second drive portion 22 of the other piezoelectric drive part 20 are respectively placed at positions that are point-symmetrical with respect to the movable part 10. With this placement, the rotational width of the movable part 10 can be widened in accordance with the drive control of the two second drive portions 22. In addition, the rotational width of the movable part 10 can be widened with fewer components than in the case where two second drive portions 22 are placed in one piezoelectric drive part 20 as in Embodiment 2 described later.

In the configurations shown in FIG. 4A and FIG. 4B, the fixing parts 30, which are placed in the gap regions G on both sides (the X-axis positive side and the X-axis negative side) of the rotation axis R10, are connected to each other. Accordingly, since the two fixing parts 30 are integrated with each other, it is easier to handle the pair of fixing parts 30 when installing the pair of fixing parts 30 on the installation surface B11. Therefore, the pair of fixing parts 30 can be easily and stably fixed to the installation surface B11.

### Embodiment 2

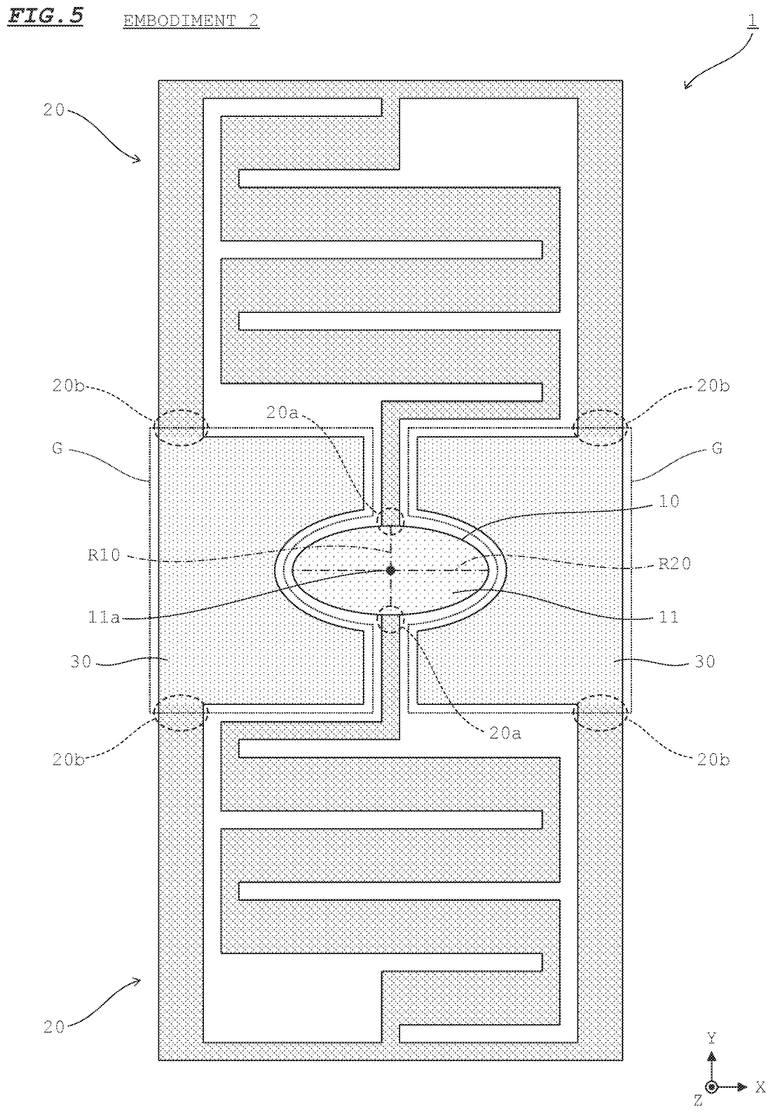

FIG. 5 is a plan view schematically showing a configuration of the piezoelectric drive element 1 according to Embodiment 2.

In the configuration in FIG. 5, the placement and the configuration of the pair of piezoelectric drive parts 20 are different from those in Embodiment 1 described above, and the shape of each fixing part 30 in a plan view is further different from that in Embodiment 1 described above. That is, two end portions 20b are provided on the opposite sides of the end portion 20a of each piezoelectric drive part 20, and the two end portions 20b are connected to the pair of fixing parts 30, respectively. In the present embodiment as well, in a plan view, the gap region G is formed on each of the X-axis positive side and the X-axis negative side of the rotation axis R10, and a region that is outside the movable part 10 and that is located between the pair of piezoelectric drive parts 20 is the gap region G. The fixing parts 30 are placed in the gap regions G on both sides, respectively.

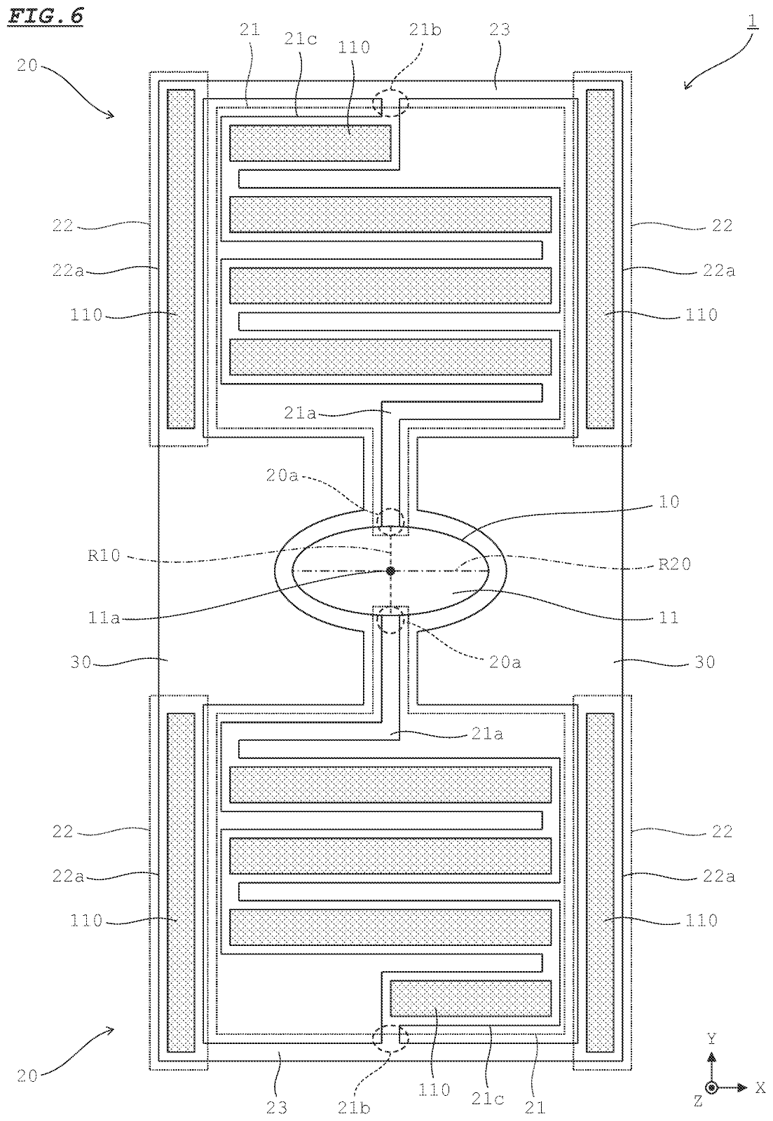

FIG. 6 is a plan view schematically showing a configuration of the pair of piezoelectric drive parts 20.

Each piezoelectric drive part 20 includes a first drive portion 21, two second drive portions 22, and a coupling portion 23. The two second drive portions 22 in one piezoelectric drive part 20 are respectively provided on the X-axis positive side and the X-axis negative side of the first drive portion 21 and placed at positions that are line-symmetrical with respect to the rotation axis R10. Each of the two second drive portions 22 in one piezoelectric drive part 20 is connected to the end portion 21b of the first drive portion 21 in the piezoelectric drive part 20 via the coupling portion 23. That is, in the present embodiment as well, each second drive portion 22 is interposed between the first drive portion 21 and the fixing part 30 and connects the end portion 21b of the first drive portion 21 and the fixing part 30. The end portion 21b is located on the rotation axis R10.

In a plan view, the two second drive portions 22 in one piezoelectric drive part 20 extend in one direction parallel to the rotation axis R10 from the pair of fixing parts 30 at the edges on both sides in the width direction (X-axis direction) of the piezoelectric drive element 1, and the two second drive portions 22 in the other piezoelectric drive part 20 extend in another direction parallel to the rotation axis R10 from the pair of fixing parts 30 at the edges on both sides in the width direction (X-axis direction) of the piezoelectric drive element 1. In addition, in a plan view, the first drive portion 21 in one piezoelectric drive part 20 is placed in a range located between the two second drive portions 22, and the first drive portion 21 in the other piezoelectric drive part 20 is placed in a range located between the two second drive portions 22.

In a plan view, the pair of fixing parts 30 are placed in the left and right gap regions G such that the contour of the piezoelectric drive element 1 has a quadrangular shape (here, a rectangular shape). Here, the pair of fixing parts 30 are placed so as to extend over the entire gap regions G with at least an acceptable minimum gap with respect to the pair of piezoelectric drive parts 20 and the movable part 10, that is, with a minimum gap that allows the pair of piezoelectric drive parts 20 and the movable part 10 to be stably moved.

Here, in the present embodiment, each second drive portion 22 is driven in accordance with first drive control or second drive control.

In the first drive control, the two second drive portions 22 are driven such that the pair of coupling portions 23 repeatedly rotate about the rotation axis R10 in the same cycle in synchronization with the pair of first drive portions 21. Since the pair of coupling portions 23, which respectively support the end portions 21b of the pair of first drive portions 21, repeatedly rotate in the same cycle in synchronization with the pair of first drive portions 21 as described above, the rotation of the pair of first drive portions 21 is enhanced. Accordingly, as in Embodiment 1, the rotational width of the movable part 10 and the mirror 11 is increased. Therefore, the range of scanning with the light reflected by the mirror 11 can be expanded.

In the second drive control, the two second drive portions 22 are driven such that the pair of coupling portions 23 are displaced in directions opposite to each other in the Z-axis direction. Accordingly, the movable part 10 and the mirror 11 rotate about a rotation axis R20. The rotation axis R20 is an axis that passes through the center 11a and that is parallel to the X axis. By controlling the second drive portions 22 as described above, in combination with the drive by the first drive portion 21, the movable part 10 and the mirror 11 can be biaxially driven about the two rotation axes R10 and R20. Therefore, scanning can be performed two-dimensionally with the light reflected by the mirror 11.

In the configuration in FIG. 5 and FIG. 6, the end portions 20a of the pair of piezoelectric drive parts 20 are placed on the rotation axis R10 in a plan view, but as in Embodiment 1 described above, the end portions 20a of the pair of piezoelectric drive parts 20 may be connected to the movable part 10 at positions displaced from the rotation axis R10 in opposite directions by the same distance.

### Effects of Embodiment 2

According to the present embodiment, the following effects are achieved in addition to the same effects as those of Embodiment 1.

The pair of piezoelectric drive parts 20 each include the first drive portion 21 which rotates the movable part 10 about the rotation axis R10 and the second drive portions 22 which drive the end portion 21b of the first drive portion 21 up and down (in the Z-axis direction). According to this configuration, in accordance with the drive control of the second drive portion 22, the rotational width of the movable part 10 can be widened, or the movable part 10 can be rotated in a direction perpendicular to the rotation axis R10 (in the direction of the rotation axis R20).

More specifically, in each piezoelectric drive part 20, the second drive portions 22 are respectively placed at the positions that are line-symmetrical with respect to the rotation axis R10. According to this configuration, the rotational width of the movable part 10 can be widened in accordance with the first drive control of the second drive portions 22, or the movable part 10 can be rotated in the direction perpendicular to the rotation axis R10 (the direction of the rotation axis R20) as a rotation axis in accordance with the second drive control of the second drive portions 22.

### Modification 1 of Embodiment 2

In Embodiment 2 described above, as shown in FIG. 5, the position of the outer side in the X-axis direction of each fixing part 30 coincides with the position of the outer edge in the X-axis direction of the piezoelectric drive part 20. However, in the present modification, the position of the outer side in the X-axis direction of each fixing part 30 is displaced inward. Hereinafter, the configuration different from that of Embodiment 2 described above will be described.

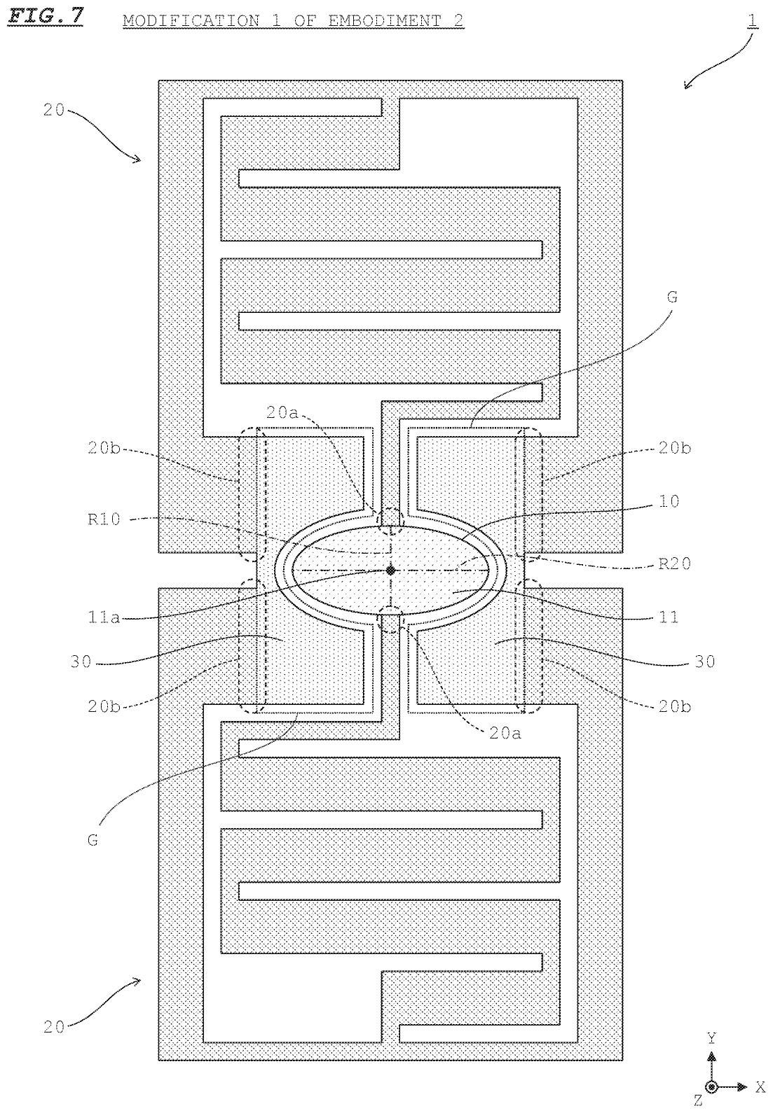

FIG. 7 is a plan view schematically showing a configuration of the piezoelectric drive element 1 according to Modification 1 of Embodiment 2.

In the present modification, as compared to Embodiment 2 in FIG. 5, the end portion 20b on the X-axis positive side of each piezoelectric drive part 20 and the end portion 20b on the X-axis negative side of each piezoelectric drive part 20 are both displaced to the center 11a side. Accordingly, the outer side in the X-axis direction of each gap region G is displaced inward as compared to Embodiment 2 in FIG. 5. In the present modification as well, in a plan view, the gap region G is formed on each of the X-axis positive side and the X-axis negative side of the rotation axis R10, and a region that is outside the movable part 10 and that is located between the pair of piezoelectric drive parts 20 is the gap region G. The fixing parts 30 are placed in the gap regions G on both sides, respectively.

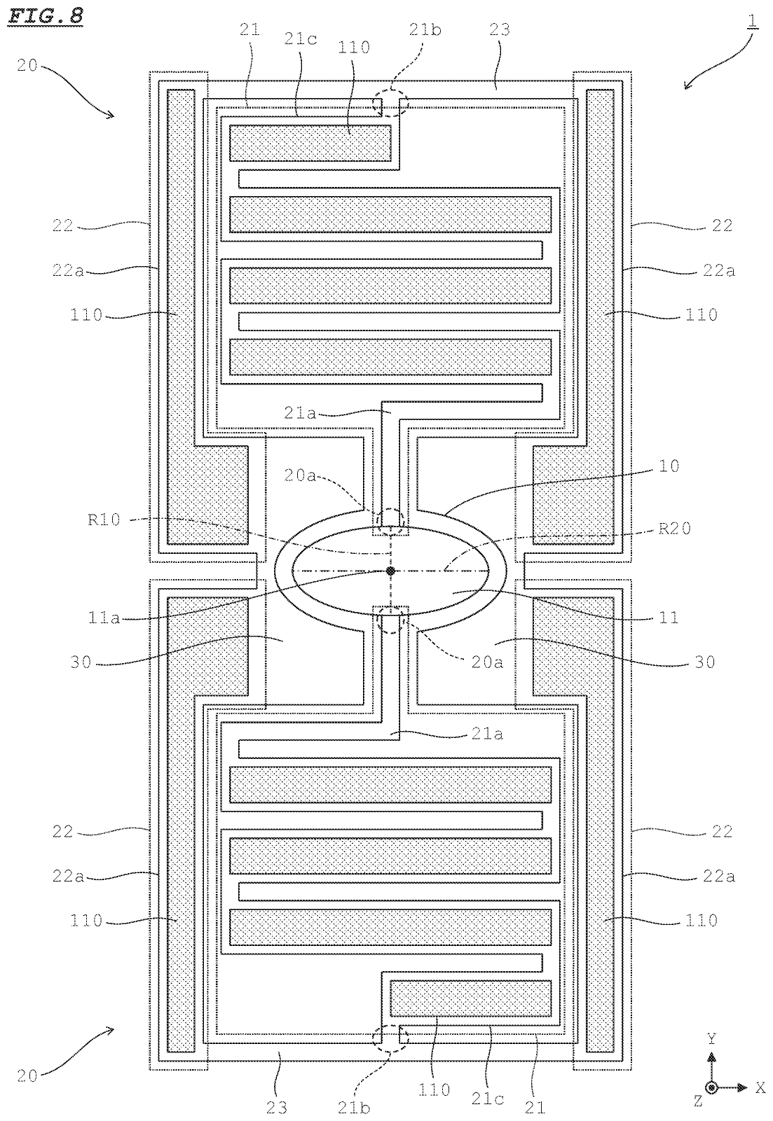

FIG. 8 is a plan view schematically showing a configuration of the pair of piezoelectric drive parts 20.

An end portion on the center 11a side of each second drive portion 22 is displaced to the center 11a side as compared to Embodiment 2 described above. An end portion on the center 11a side of the piezoelectric actuator 110 of each second drive portion 22 is also displaced to the center 11a side as compared to Embodiment 2 described above. In the present modification as well, the two second drive portions 22 in one piezoelectric drive part 20 are placed at positions that are line-symmetrical with respect to the rotation axis R10.

In a plan view, the two second drive portions 22 in one piezoelectric drive part 20 extend in one direction parallel to the rotation axis R10 from the pair of fixing parts 30 at the edges on both sides in the width direction (X-axis direction) of the piezoelectric drive element 1, and the two second drive portions 22 in the other piezoelectric drive part 20 extend in another direction parallel to the rotation axis R10 from the pair of fixing parts 30 at the edges on both sides in the width direction (X-axis direction) of the piezoelectric drive element 1. Each second drive portion 22 has an L-shape in a plan view. In addition, in a plan view, the first drive portion 21 in one piezoelectric drive part 20 is placed in a range located between the two second drive portions 22, and the first drive portion 21 in the other piezoelectric drive part 20 is placed in a range located between the two second drive portions 22.

In a plan view, the pair of fixing parts 30 are placed in the left and right gap regions G such that the contour of the piezoelectric drive element 1 has a quadrangular shape (here, a rectangular shape). Here, the pair of fixing parts 30 are placed so as to extend over the entire gap regions G with at least an acceptable minimum gap with respect to the pair of piezoelectric drive parts 20 and the movable part 10, that is, with a minimum gap that allows the pair of piezoelectric drive parts 20 and the movable part 10 to be stably moved.

In the present modification as well, the second drive portions 22 are driven in accordance with the first drive control or the second drive control. Accordingly, the rotational width of the movable part 10 can be widened in accordance with the first drive control of the second drive portions 22, or the movable part 10 can be rotated in the direction perpendicular to the rotation axis R10 (the direction of the rotation axis R20) as a rotation axis in accordance with the second drive control of the second drive portions 22.

### Modification 2 of Embodiment 2

In Modification 1 of Embodiment 2, as shown in FIG. 7, the two piezoelectric drive parts 20 opposing each other in the Y-axis direction are placed on the X-axis positive side and the X-axis negative side of the movable part 10 with a gap therebetween. On the other hand, in the present modification, the two piezoelectric drive parts 20 opposing each other in the Y-axis direction are connected to each other. Hereinafter, the configuration different from that of Modification 1 of Embodiment 2 will be described.

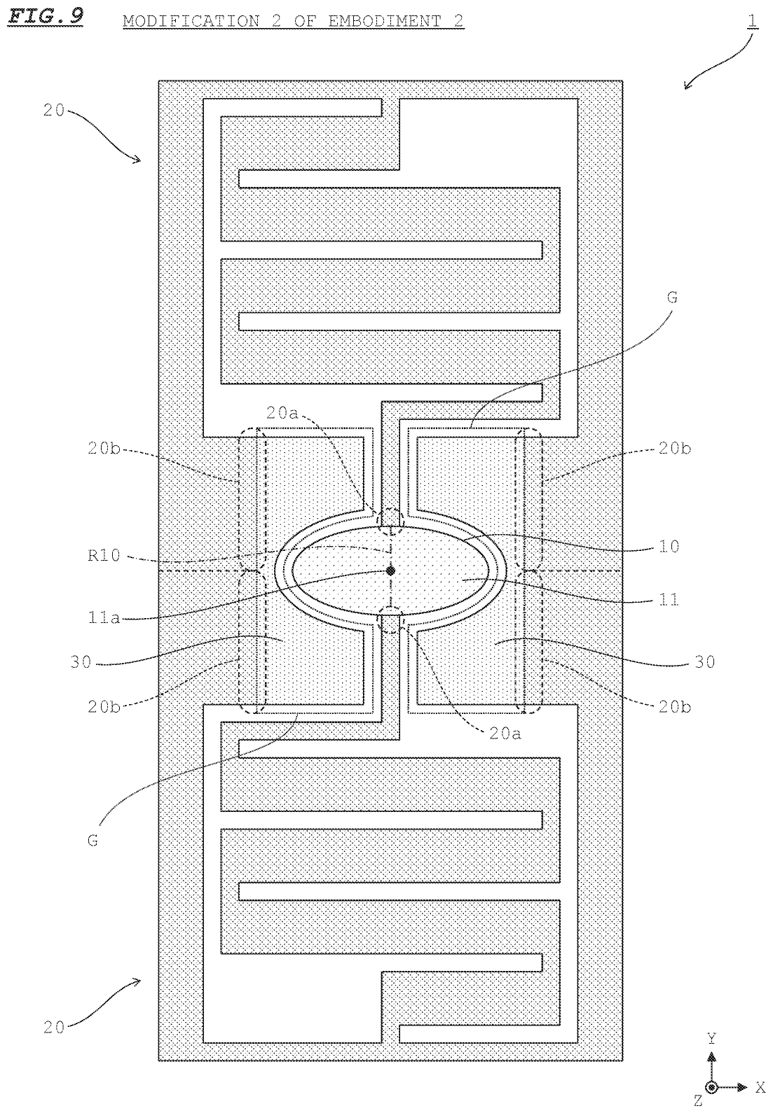

FIG. 9 is a plan view schematically showing a configuration of the piezoelectric drive element 1 according to Modification 2 of Embodiment 2.

In the present modification, the two piezoelectric drive parts 20 opposing each other in the Y-axis direction are connected to each other on the X-axis positive side and the X-axis negative side of the movable part 10 without any gap therebetween. Accordingly, the end portions 20b of the piezoelectric drive part 20 on the Y-axis positive side and the end portions 20b of the piezoelectric drive part 20 on the Y-axis negative side are connected to each other without any gap therebetween.

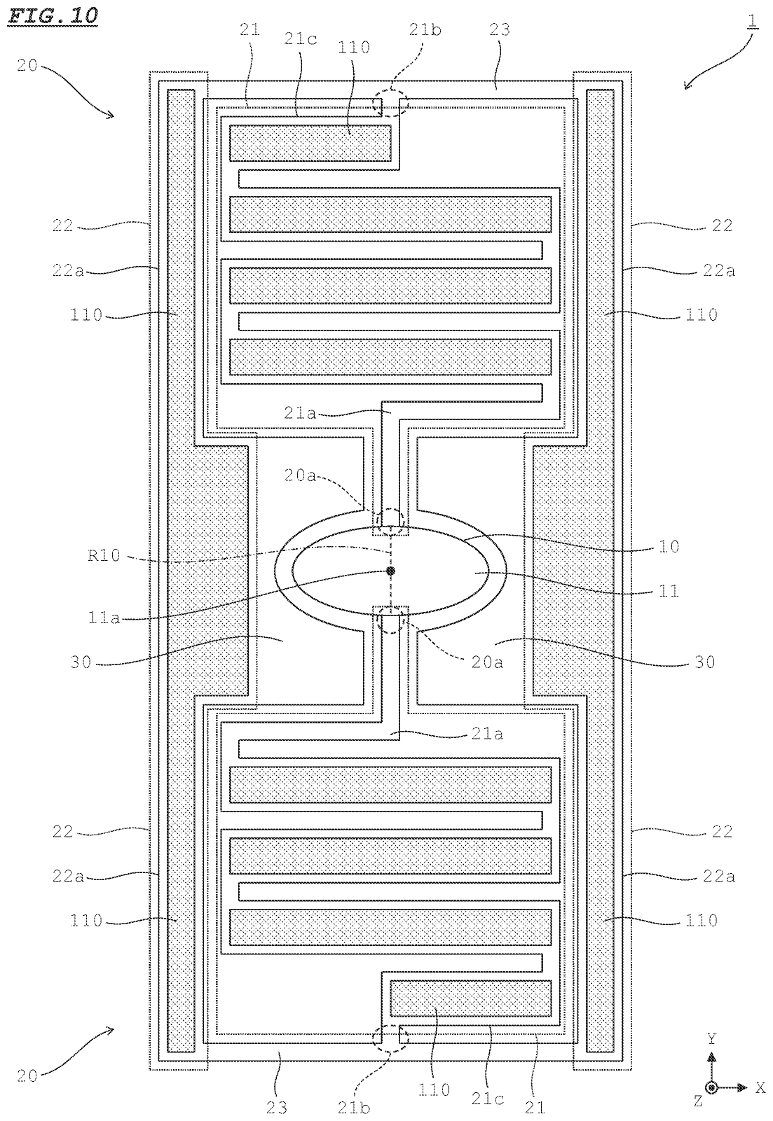

FIG. 10 is a plan view schematically showing a configuration of the pair of piezoelectric drive parts 20.

In the present modification, one second drive portion 22 is placed on each of the X-axis positive side and the X-axis negative side of the pair of piezoelectric drive parts 20. The second drive portions 22 of the present modification extend from an end portion on the Y-axis positive side to an end portion on the Y-axis negative side of the piezoelectric drive element 1. That is, in the present modification, the second drive portions 22 of the two piezoelectric drive parts 20 on one side (X-axis positive side) with respect to the rotation axis R10 are shared by the pair of piezoelectric drive parts 20, and the second drive portions 22 of the two piezoelectric drive parts 20 on the other side (X-axis negative side) with respect to the rotation axis R10 are shared by the pair of piezoelectric drive parts 20.

In the present modification, the entirety of each second drive portion 22 bends in one direction when a voltage is applied thereto, so that the pair of coupling portions 23 cannot be displaced in directions opposite to each other. Therefore, in the present modification, the above-described second drive control cannot be performed.

On the other hand, in the present modification as well, the pair of coupling portions 23 can be rotated about the rotation axis R10 in the same direction by driving the two second drive portions 22 in phases opposite to each other. Therefore, in the present modification as well, the above-described first drive control can be performed. That is, in the present modification, in the first drive control, the two second drive portions 22 are repeatedly driven in opposite phases such that the pair of coupling portions 23 rotate about the rotation axis R10 in the same phase in synchronization with the pair of first drive portions 21. Accordingly, as in the configuration of Embodiment 2 shown in FIG. 5 and FIG. 6, the rotational width of the movable part 10 can be widened.

### Embodiment 3

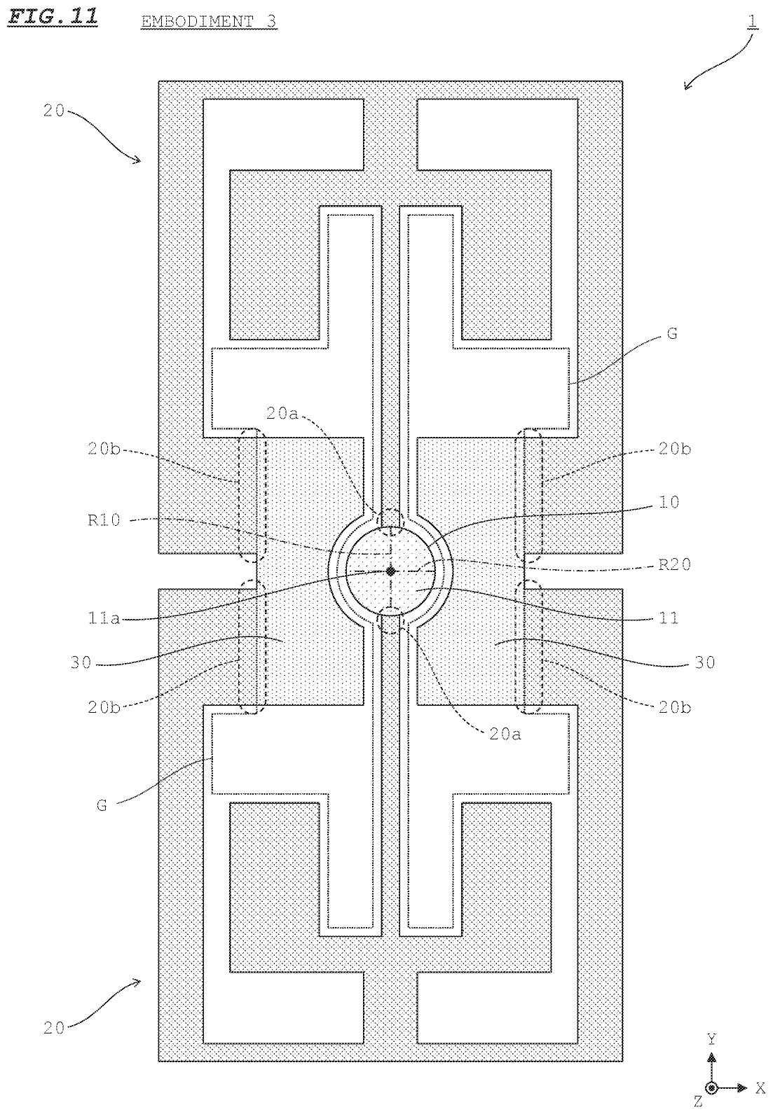

As shown in FIG. 11, in the piezoelectric drive element 1 of Embodiment 3, as compared to Modification 1 of Embodiment 2 shown in FIG. 7 and FIG. 8, the meander-type drive portions of the piezoelectric drive parts 20 are changed to tuning fork-type drive portions. In addition, the range of each gap region G becomes larger due to the change of each piezoelectric drive part 20. The other configuration is the same as in Modification 1 of Embodiment 2.

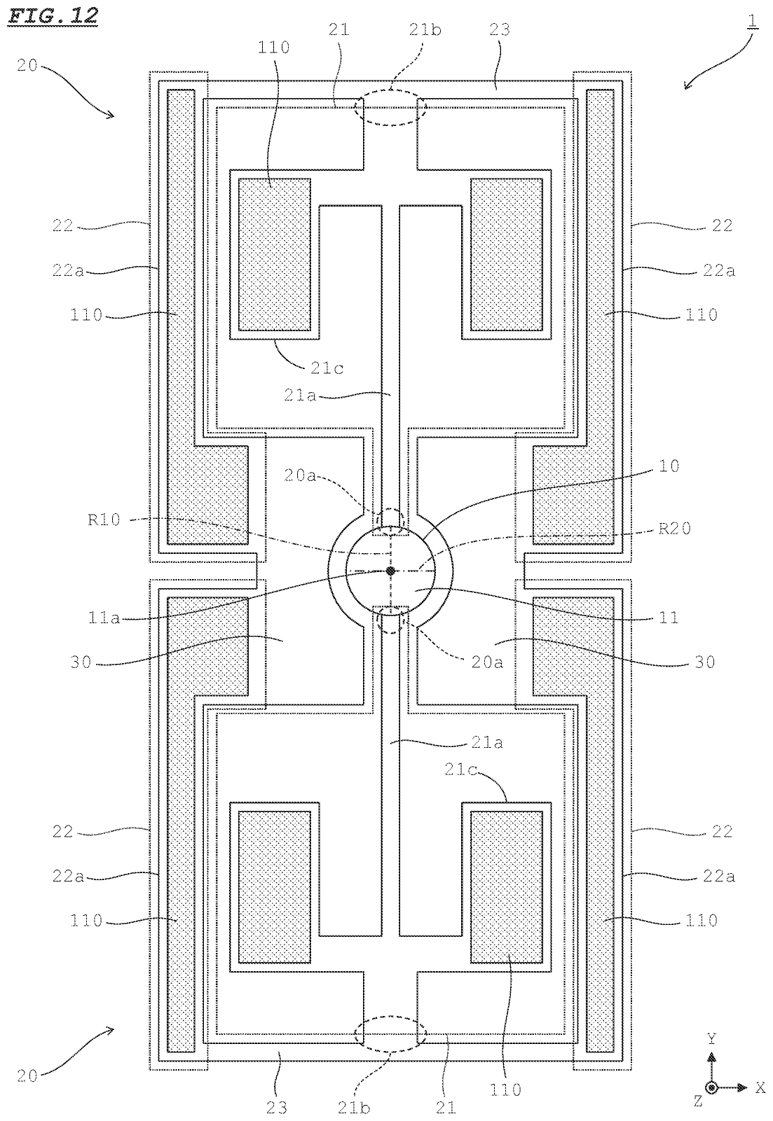

As shown in FIG. 12, each piezoelectric drive part 20 includes a first drive portion 21, a pair of second drive portions 22, and a coupling portion 23. The first drive portion 21 includes a coupling portion 21a extending along the rotation axis R10, and is connected to the movable part 10 via the coupling portion 21a. The end portion 21b of the first drive portion 21 is located on the rotation axis R10, and is connected to the coupling portion 23. The first drive portion 21 includes a so-called tuning fork-type actuator. That is, the first drive portion 21 includes a pair of vibration portions 21c coupled to each other so as to form a tuning fork shape. Each vibration portion 21c is configured in the same manner as in Embodiment 1 described above. As shown in FIG. 11 and FIG. 12, the gap regions G of the present modification are regions surrounded by the pair of vibration portions 21c of the first drive portion 21, the second drive portions 22, and the movable part 10.

In a plan view, the two second drive portions 22 in one piezoelectric drive part 20 extend in one direction parallel to the rotation axis R10 from the pair of fixing parts 30 at the edges on both sides in the width direction (X-axis direction) of the piezoelectric drive element 1, and the two second drive portions 22 in the other piezoelectric drive part 20 extend in another direction parallel to the rotation axis R10 from the pair of fixing parts 30 at the edges on both sides in the width direction (X-axis direction) of the piezoelectric drive element 1. Each second drive portion 22 has an L-shape in a plan view. In addition, in a plan view, the first drive portion 21 in one piezoelectric drive part 20 is placed in a range located between the two second drive portions 22, and the first drive portion 21 in the other piezoelectric drive part 20 is placed in a range located between the two second drive portions 22.

In a plan view, the pair of fixing parts 30 are placed in the left and right gap regions G such that the contour of the piezoelectric drive element 1 has a quadrangular shape (here, a rectangular shape). Here, the pair of fixing parts 30 are placed so as to extend over partial regions in the gap regions G (regions obtained by cutting the region of the movable part 10 from the regions of quadrangular shapes sandwiching the movable part 10) with at least an acceptable minimum gap with respect to the pair of piezoelectric drive parts 20 and the movable part 10, that is, with a minimum gap that allows the pair of piezoelectric drive parts 20 and the movable part 10 to be stably moved.

However, the present invention is not limited thereto, and each fixing part 30 may be placed so as to extend over the entire gap region G. In addition, as in Embodiment 2 shown in FIG. 5 and FIG. 6, in a plan view, the pair of fixing parts 30 may be placed so as to extend to the edge in the width direction of the piezoelectric drive element 1, and each second drive portion 22 may be provided so as to extend parallel to the rotation axis R10 in a straight manner from the fixing part 30.

A voltage is applied to each piezoelectric actuator 110 of each first drive portion 21 such that a state where one vibration portion 21c is displaced in the Z-axis positive direction and the other vibration portion 21c is displaced in the Z-axis negative direction and a state where the one vibration portion 21c is displaced in the Z-axis negative direction and the other vibration portion 21c is displaced in the Z-axis positive direction are repeated. Accordingly, the movable part 10, which is connected via the coupling portion 21a, and the mirror 11 repeatedly rotate about the rotation axis R10.

In the present embodiment as well, the second drive portions 22 are driven in accordance with the first drive control or the second drive control. Accordingly, as in Modification 1 of Embodiment 2, the rotational width of the movable part 10 can be widened in accordance with the first drive control of the second drive portions 22, or the movable part 10 can be rotated in the direction perpendicular to the rotation axis R10 (the direction of the rotation axis R20) as a rotation axis in accordance with the second drive control of the second drive portions 22.

### Modification of Embodiment 3

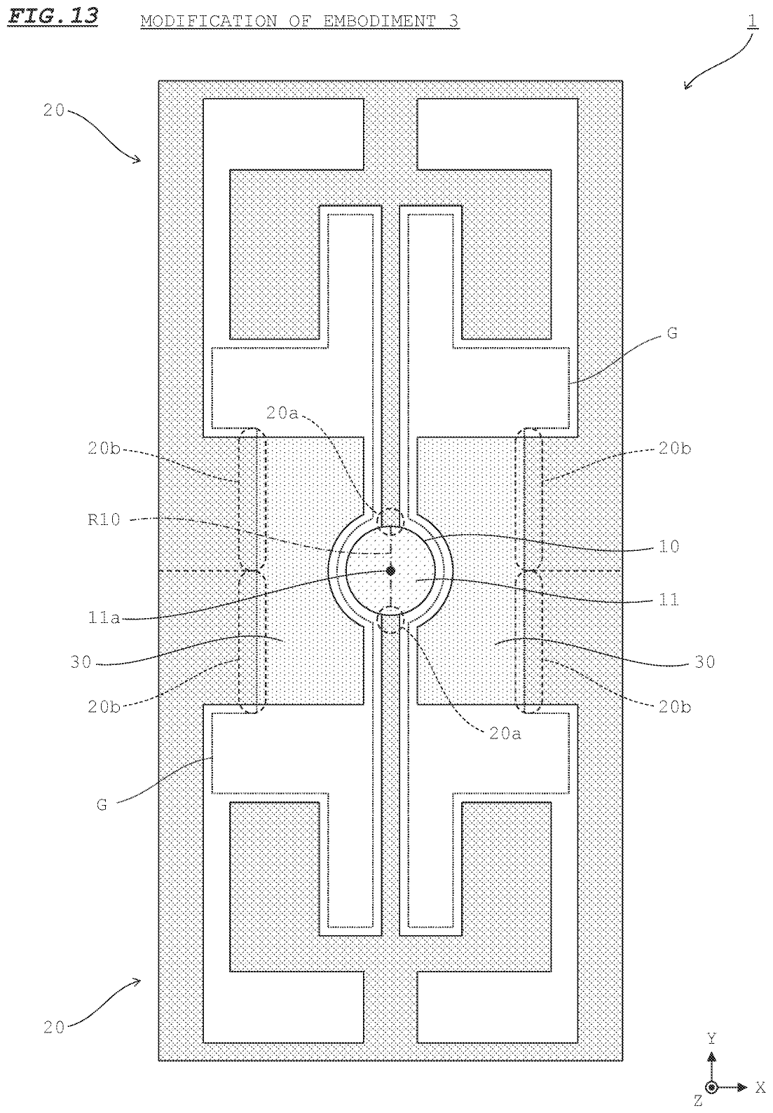

As shown in FIG. 13, in the piezoelectric drive element 1 of the present modification, as compared to Modification 2 of Embodiment 2 shown in FIG. 9, the meander-type drive portions of the piezoelectric drive parts 20 are changed to tuning fork-type drive portions. The other configuration is the same as in Modification 2 of Embodiment 2.

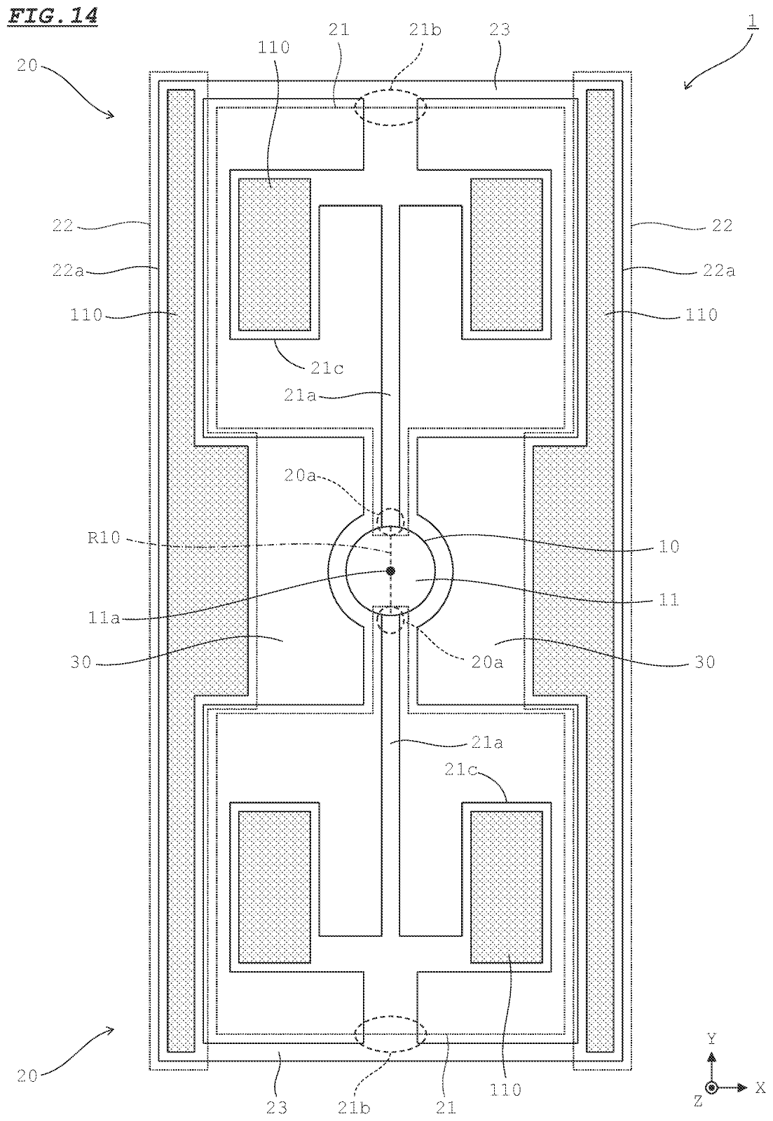

As shown in FIG. 14, the first drive portions 21 are configured in the same manner as the first drive portions 21 of Embodiment 3 shown in FIG. 12. In the present modification, the second drive portions 22 are driven in accordance with the first drive control as in Modification 2 of Embodiment 2. Accordingly, the rotational width of the movable part 10 can be widened.

### Embodiment 4

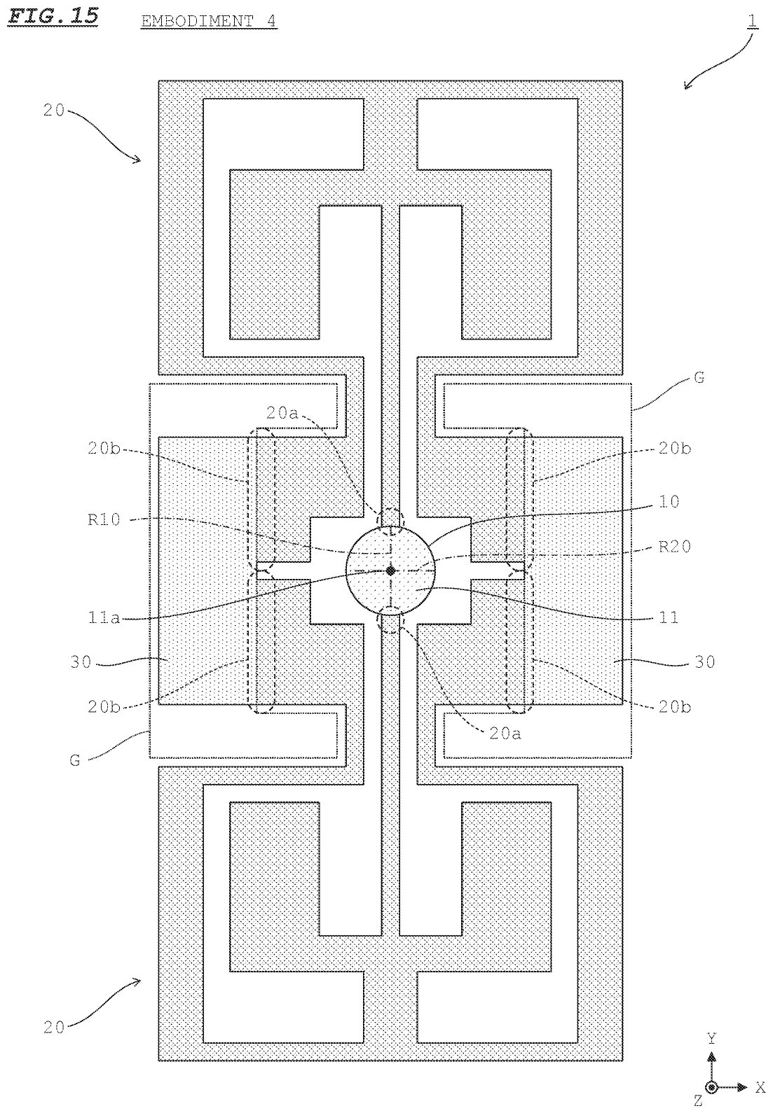

As shown in FIG. 11, in Embodiment 3, each fixing part 30 is placed on the inner side of the end portion 20b of each piezoelectric drive part 20 with respect to the center 11a. On the other hand, in the present embodiment, as shown in FIG. 15, each fixing part 30 is placed on the outer side of the end portion 20b of each piezoelectric drive part 20 with respect to the center 11a. Hereinafter, the configuration different from that of Embodiment 3 will be described.

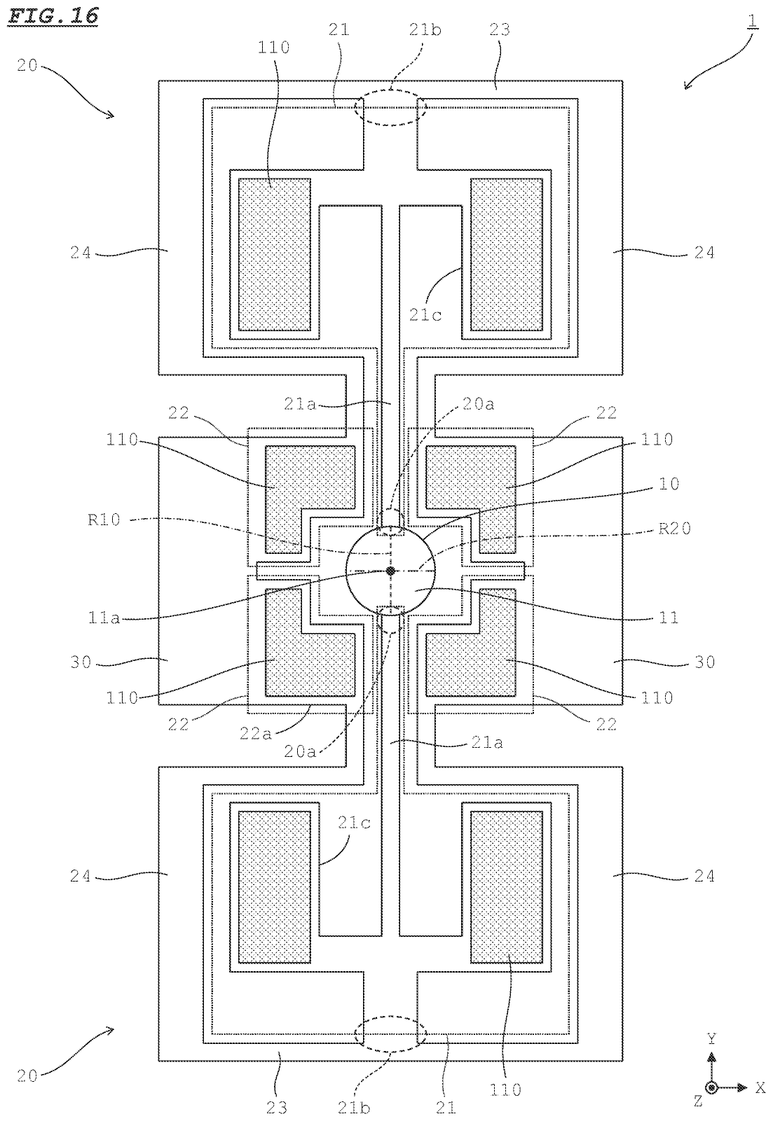

As shown in FIG. 16, each piezoelectric drive part 20 includes a first drive portion 21, a pair of second drive portions 22, a coupling portion 23, and a pair of coupling portions 24. Each second drive portion 22 is placed between the movable part 10 and the fixing part 30. Each second drive portion 22 is connected to the coupling portion 23 via the coupling portion 24. One second drive portion 22 includes one vibration portion 22a. The second drive portion 22 is placed adjacent to the coupling portion 21a and the movable part 10, and each fixing part 30 is placed on the outer side of the second drive portion 22 with respect to the center 11a. As shown in FIG. 15 and FIG. 16, each gap region G of the present embodiment is a region that is located between the coupling portions 24 in the Y-axis direction and that is located on the outer side of the coupling portions 24 and the second drive portions 22 with respect to the center 11a in the X-axis direction.

In a plan view, the two second drive portions 22 in one piezoelectric drive part 20 are placed on a side in one direction parallel to the rotation axis R10 at a position adjacent to the movable part 10 and the coupling portions 24 placed along the rotation axis R10, and the two second drive portions 22 in the other piezoelectric drive part 20 are placed on a side in another direction parallel to the rotation axis R10 at a position adjacent to the movable part 10 and coupling portions 24 placed along the rotation axis R10. In addition, in a plan view, in the one piezoelectric drive part 20, the first drive portion 21 is placed on the side in the one direction parallel to the rotation axis R10, with respect to the two second drive portions 22, and in the other piezoelectric drive part 20, the first drive portion 21 is placed on the side in the other direction parallel to the rotation axis R10, with respect to the two second drive portions 22.

In a plan view, the pair of fixing parts 30 are placed in the left and right gap regions G such that the contour of the piezoelectric drive element 1 has a quadrangular shape (here, a rectangular shape). Here, the pair of fixing parts 30 are placed so as to extend over partial regions in the gap regions G (regions obtained by cutting the region of the movable part 10 and the second drive portions 22 from the regions of quadrangular shapes sandwiching the movable part 10) with at least an acceptable minimum gap with respect to the pair of piezoelectric drive parts 20 and the movable part 10, that is, with a minimum gap that allows the pair of piezoelectric drive parts 20 and the movable part 10 to be stably moved. However, the present invention is not limited thereto, and each fixing part 30 may be placed so as to extend over the entire gap region G.

In the present embodiment as well, the second drive portions 22 are driven in accordance with the first drive control or the second drive control. Accordingly, as in Embodiment 3 described above, the rotational width of the movable part 10 can be widened in accordance with the first drive control of the second drive portions 22, or the movable part 10 can be rotated in the direction perpendicular to the rotation axis R10 (the direction of the rotation axis R20) as a rotation axis in accordance with the second drive control of the second drive portions 22.

### Modification of Embodiment 4

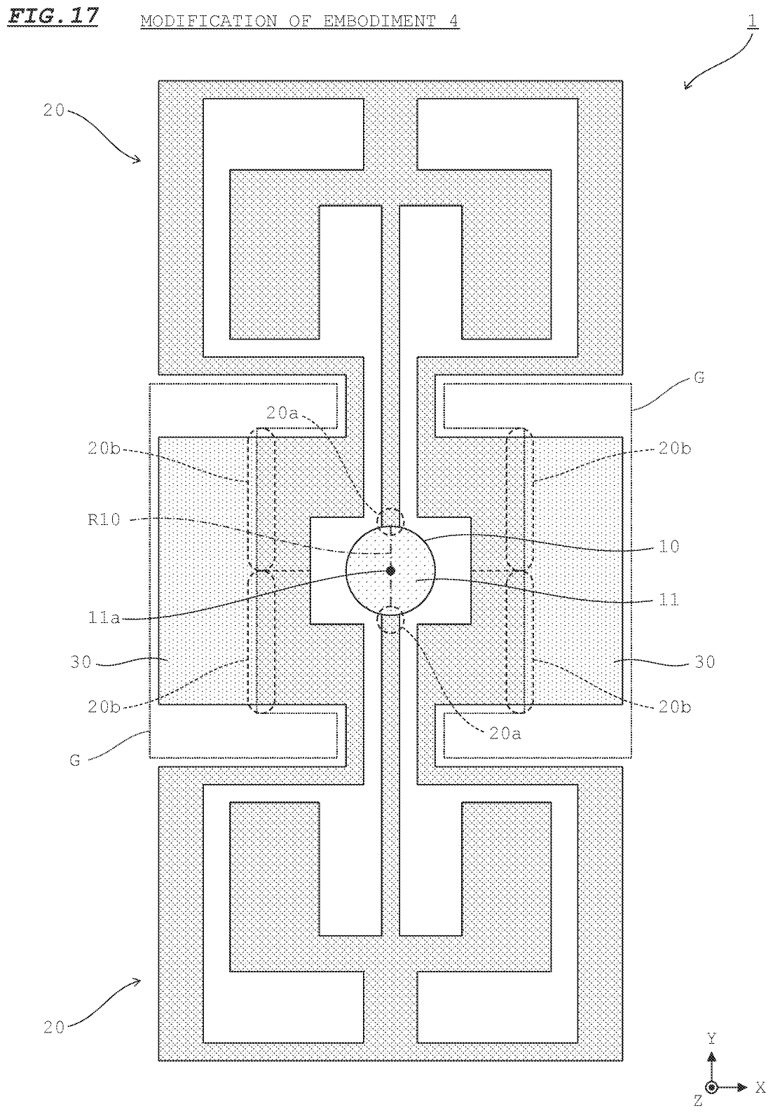

As shown in FIG. 17, in the piezoelectric drive element 1 of the present modification, as compared to Embodiment 4 shown in FIG. 15, the two piezoelectric drive parts 20 opposing each other in the Y-axis direction are connected to each other as in the modification of Embodiment 3 shown in FIG. 13. Hereinafter, the configuration different from that of Embodiment 4 will be described.

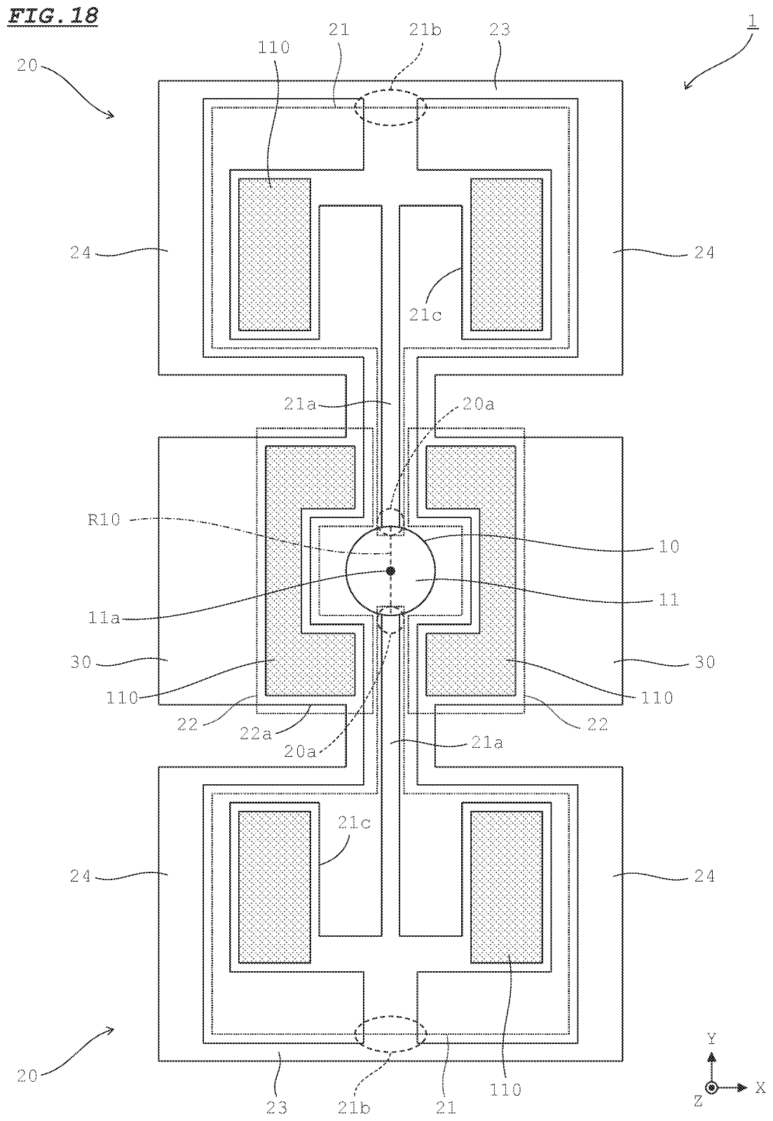

As shown in FIG. 18, in the present modification, the two second drive portions 22 placed on one side (X-axis positive side) with respect to the rotation axis R10 in Embodiment 4 are shared by the pair of piezoelectric drive parts 20, and the two second drive portions 22 placed on the other side (X-axis negative side) with respect to the rotation axis R10 in Embodiment 4 are shared by the pair of piezoelectric drive parts 20.

In the present modification, the entirety of each second drive portion 22 bends in one direction when a voltage is applied thereto, so that the pair of coupling portions 23 cannot be displaced in directions opposite to each other. Therefore, in the present modification, the above-described second drive control cannot be performed.

On the other hand, in the present modification as well, the pair of coupling portions 23 can be rotated about the rotation axis R10 in the same direction by driving the two second drive portions 22 in phases opposite to each other. Therefore, in the present modification as well, the above-described first drive control can be performed. Accordingly, the rotational width of the movable part 10 can be widened.

### Embodiment 5

In Embodiments 1 to 4 and the modifications thereof, each fixing part 30 is placed in the gap region G which is outside the movable part 10 and which is located between the pair of piezoelectric drive parts 20 in a plan view. On the other hand, in the present embodiment, the end portions in the Y-axis direction of the fixing parts 30 are placed on the outer side of the pair of piezoelectric drive parts 20 with respect to the center 11a. Hereinafter, the configuration different from that of Embodiment 1 will be described.

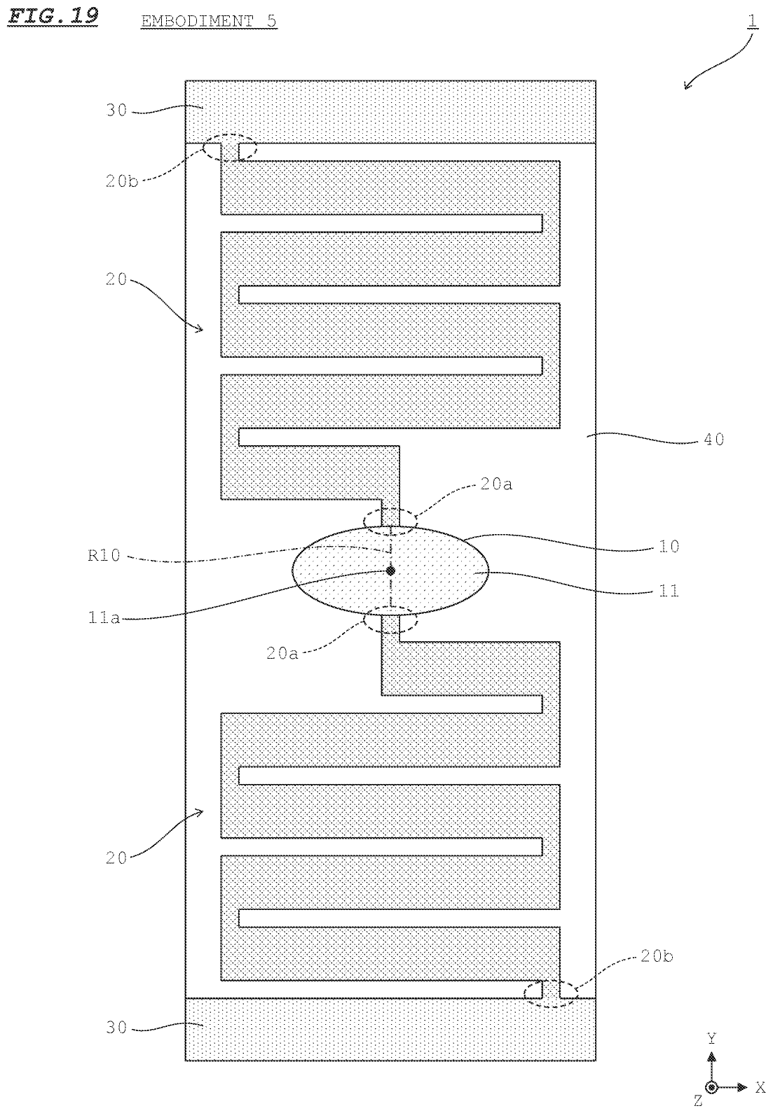

FIG. 19 is a plan view schematically showing a configuration of the piezoelectric drive element 1 according to Embodiment 5.

In the present embodiment, one fixing part 30 is placed on the outer side (Y-axis positive side) of the piezoelectric drive part 20 on the Y-axis positive side, with respect to the center 11a, and the other fixing part 30 is placed on the outer side (Y-axis negative side) of the piezoelectric drive part 20 on the Y-axis negative side, with respect to the center 11a. The end portions 20a and 20b of each piezoelectric drive part 20 are connected to the movable part 10 and the fixing part 30, respectively. The end portions 20a of the pair of piezoelectric drive parts 20 are placed on the rotation axis R10. The end portions 20a of the pair of piezoelectric drive parts 20 may be connected to the movable part 10 at positions displaced from the rotation axis R10 in opposite directions by the same distance.

The pair of fixing parts 30 are connected to each other by the connection part 40 on the Z-axis negative side of the rotation axis R10. The connection part 40 is integrally formed with the fixing parts 30 from a material that is the same as at least one of the materials forming the fixing parts 30. The connection part 40 may be made of another material different from that of the fixing part 30.

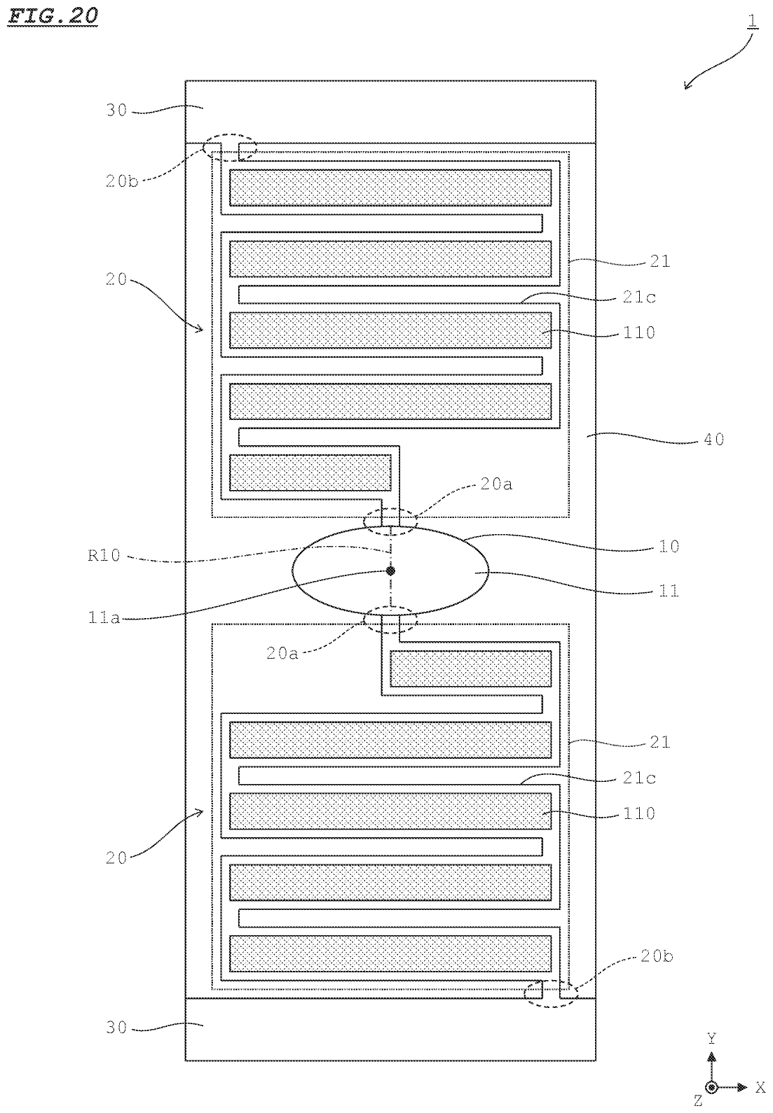

FIG. 20 is a plan view schematically showing a configuration of the pair of piezoelectric drive parts 20.

In the present embodiment, as compared to Embodiment 1, the second drive portions 22 are omitted. In addition, each first drive portion 21 of the present modification is configured in the same manner as each first drive portion 21 of Embodiment 1, and is driven in the same manner as each first drive portion 21 of Embodiment 1. Accordingly, the movable part 10 and the mirror 11 rotate about the rotation axis R10.

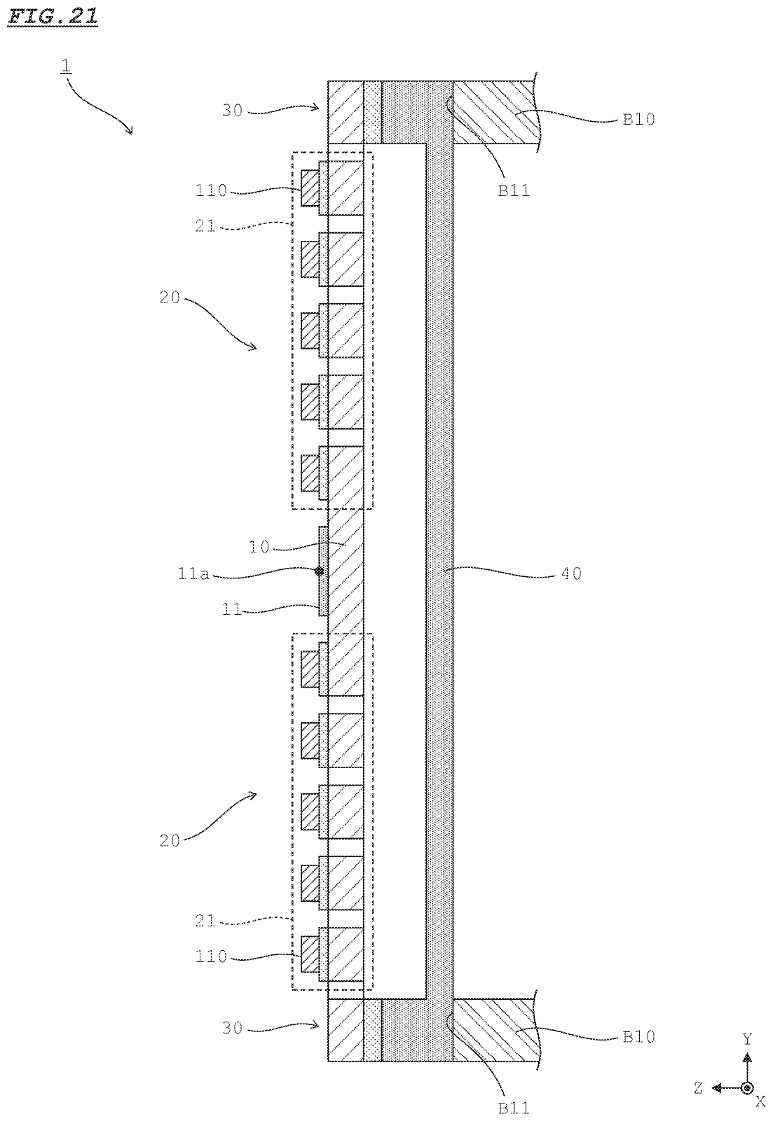

FIG. 21 is a cross-sectional view schematically showing a configuration when a cross-section of the piezoelectric drive element 1 obtained by cutting the piezoelectric drive element 1 along a plane that passes through the center 11a of the mirror 11 and that is parallel to the Y-Z plane is viewed in the X-axis negative direction.

In the Y-axis direction, the pair of fixing parts 30 define the length in the Y-axis direction of the piezoelectric drive element 1. The connection part 40 connects a lower portion of the fixing part 30 on the Y-axis positive side and a lower portion of the fixing part 30 on the Y-axis negative side. The pair of fixing parts 30 are installed on the installation surfaces B11 of a pair of base members B10.

### Effects of Embodiment 5

According to the present embodiment, the following effects are achieved.

The other ends (end portions 20b) of the pair of piezoelectric drive parts 20 are connected to the pair of fixing parts 30, respectively, and the pair of fixing parts 30 are connected to each other at a position displaced relative to the rotation axis R10 only in one direction (Z-axis negative direction). According to this configuration, since the pair of fixing parts 30 are integrated with each other, each fixing part 30 can be easily and stably fixed to the installation surface B11. In addition, the installation area of the piezoelectric drive element 1 can be reduced as compared to the case where a fixing part is placed so as to surround both the movable part 10 and the pair of piezoelectric drive parts 20 over the entire periphery.

### Modification 1 of Embodiment 5

In Embodiment 5 described above, the pair of fixing parts 30 are connected to each other at the position displaced relative to the rotation axis R10 only in the Z-axis negative direction. On the other hand, in the present modification, the pair of fixing parts 30 are connected to each other by the connection member 50 at a position displaced relative to the rotation axis R10 only in the Z-axis positive direction.

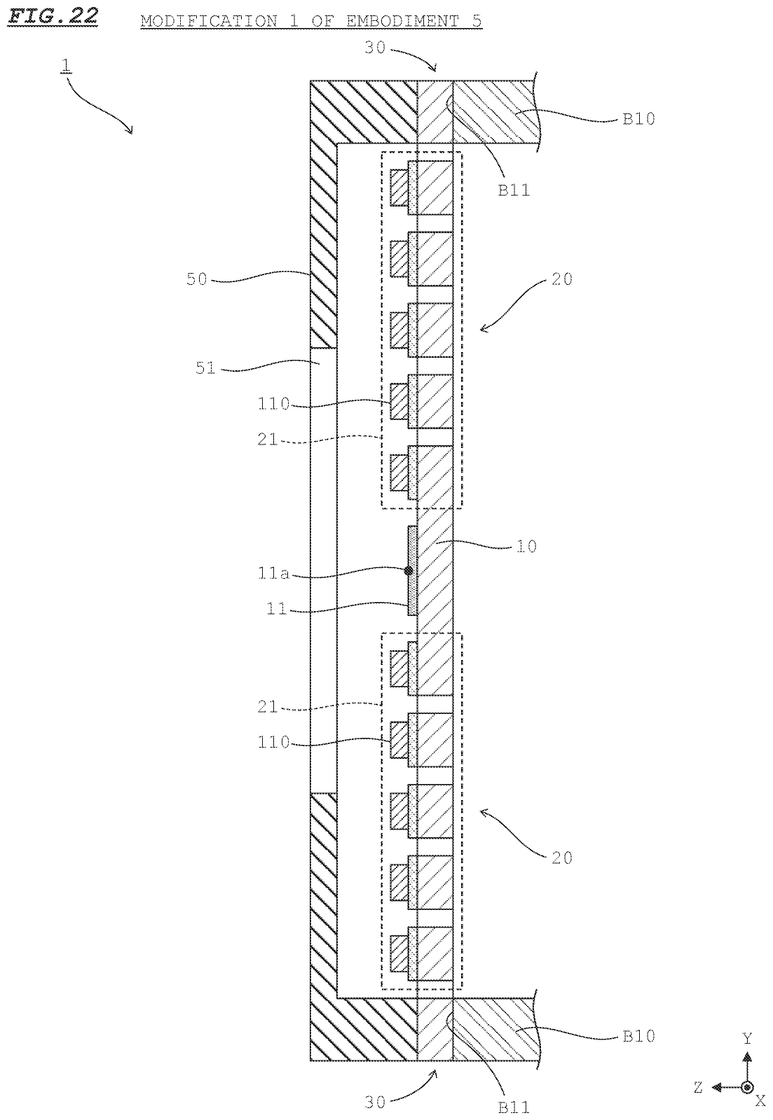

FIG. 22 is a cross-sectional view schematically showing a configuration when a cross-section of the piezoelectric drive element 1 according to Modification 1 of Embodiment 5 obtained by cutting the piezoelectric drive element 1 along a plane that passes through the center 11a of the mirror 11 and that is parallel to the Y-Z plane is viewed in the X-axis negative direction.

The connection member 50 is shaped to cover the Z-axis positive side of the mirror 11, and two end portions in the Y-axis direction of the connection member 50 are installed on the surfaces on the Z-axis positive side of the pair of fixing parts 30. In this case, a portion of the connection member 50 that covers the mirror 11 has a hole 51 formed so as to penetrate the connection member 50 in the Z-axis direction. Accordingly, light incident from the outside through the hole 51 is reflected by the mirror 11, and the light reflected by the mirror 11 is guided to the outside through the hole 51. The pair of fixing parts 30 are installed on the installation surfaces B11 of the pair of base members B10. The connection member 50 is not limited to being made of a material different from that of the fixing parts 30, and may be integrally formed with the fixing parts 30 from a material that is the same as at least one of the materials forming the fixing parts 30.

In the present modification as well, since the pair of fixing parts 30 are integrated with each other, each fixing part 30 can be easily and stably fixed to the installation surface B11. In addition, the installation area of the piezoelectric drive element 1 can be reduced as compared to the case where a fixing part is placed so as to surround both the movable part 10 and the pair of piezoelectric drive parts 20 over the entire periphery.

### Modification 2 of Embodiment 5

In Embodiment 5 and Modification 1 of Embodiment 5 described above, the pair of fixing parts 30 are connected to each other at the position displaced relative to the rotation axis R10 only in the Z-axis direction. On the other hand, in the present modification, the pair of fixing parts 30 are connected to each other by the connection part 40 at a position displaced relative to the rotation axis R10 only in the X-axis direction.

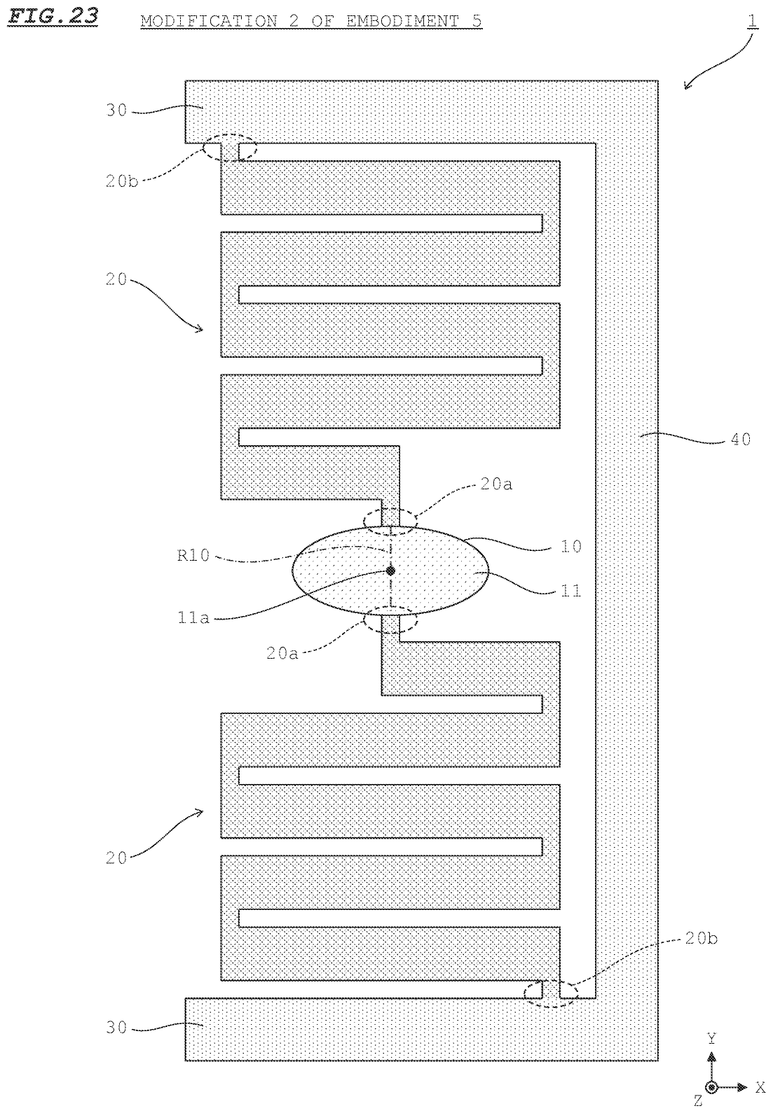

FIG. 23 is a plan view schematically showing a configuration of the piezoelectric drive element 1 according to Modification 2 of Embodiment 5.

In the present modification, an end portion on the X-axis positive side of one fixing part 30 and an end portion on the X-axis positive side of the other fixing part 30 are connected to each other by the connection part 40 on the X-axis positive side of the rotation axis R10. In the present modification, each fixing part 30 or the connection part 40 is installed on the installation surface B11 of the base member B10.

In the present modification as well, since the pair of fixing parts 30 are integrated with each other, each fixing part 30 can be easily and stably fixed to the installation surface B11. In addition, the installation area of the piezoelectric drive element 1 can be reduced as compared to the case where a fixing part is placed so as to surround both the movable part 10 and the pair of piezoelectric drive parts 20 over the entire periphery.

### Embodiment 6

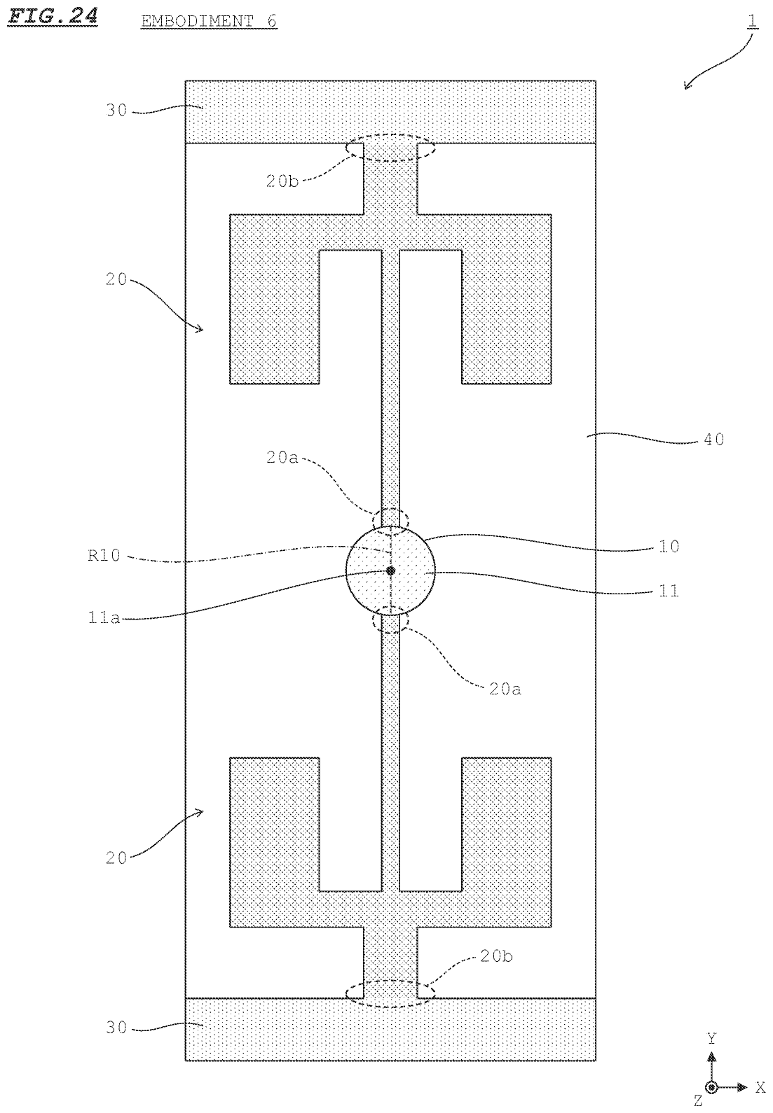

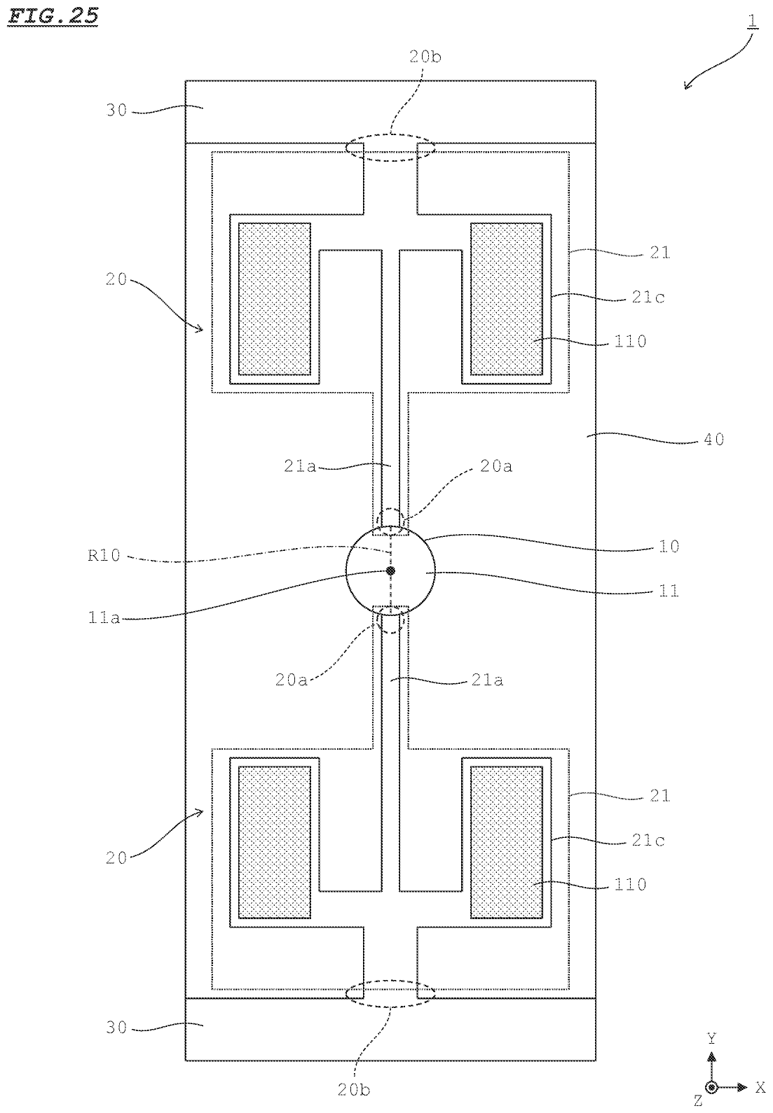

As shown in FIG. 24 and FIG. 25, in the piezoelectric drive element 1 of the present embodiment, as compared to Embodiment 5 shown in FIG. 19 and FIG. 20, the first drive portions 21 of the piezoelectric drive parts 20 are changed from a meander type to a tuning fork type. The other configuration of the present embodiment is the same as in Embodiment 5.

As shown in FIG. 25, similar to each first drive portion 21 of Embodiment 3 shown in FIG. 12, each first drive portion 21 is configured as a tuning fork type. In the present embodiment, each first drive portion 21 is driven in the same manner as in Embodiment 3 shown in FIG. 12.

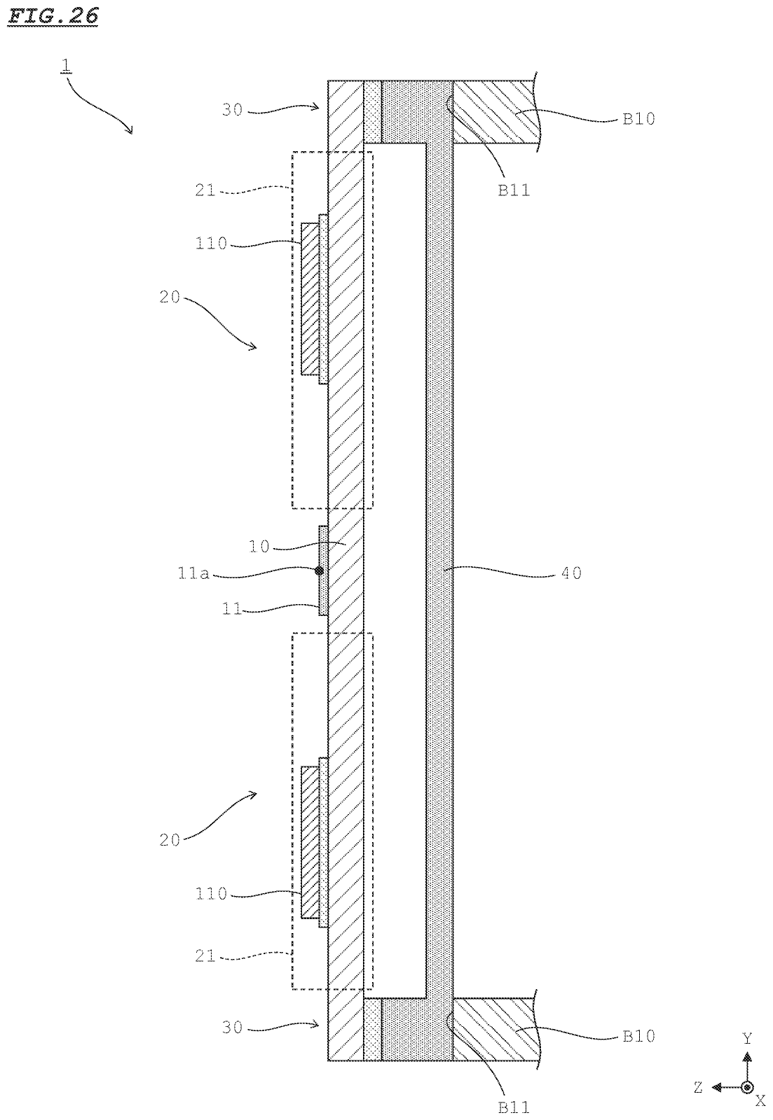

As shown in FIG. 26, the pair of fixing parts 30 are connected to each other by the connection part 40 at a position displaced relative to the rotation axis R10 only in the Z-axis negative direction. The pair of fixing parts 30 are installed on the installation surfaces B11 of the pair of base members B10.

In the present embodiment as well, since the pair of fixing parts 30 are integrated with each other, each fixing part 30 can be easily and stably fixed to the installation surface B11. In addition, the installation area of the piezoelectric drive element 1 can be reduced as compared to the case where a fixing part is placed so as to surround both the movable part 10 and the pair of piezoelectric drive parts 20 over the entire periphery.

### Modification 1 of Embodiment 6

In Embodiment 6 described above, the pair of fixing parts 30 are connected to each other at the position displaced relative to the rotation axis R10 only in the Z-axis negative direction. On the other hand, in the present modification, the pair of fixing parts 30 are connected to each other by the connection member 50 at a position displaced relative to the rotation axis R10 only in the Z-axis positive direction.

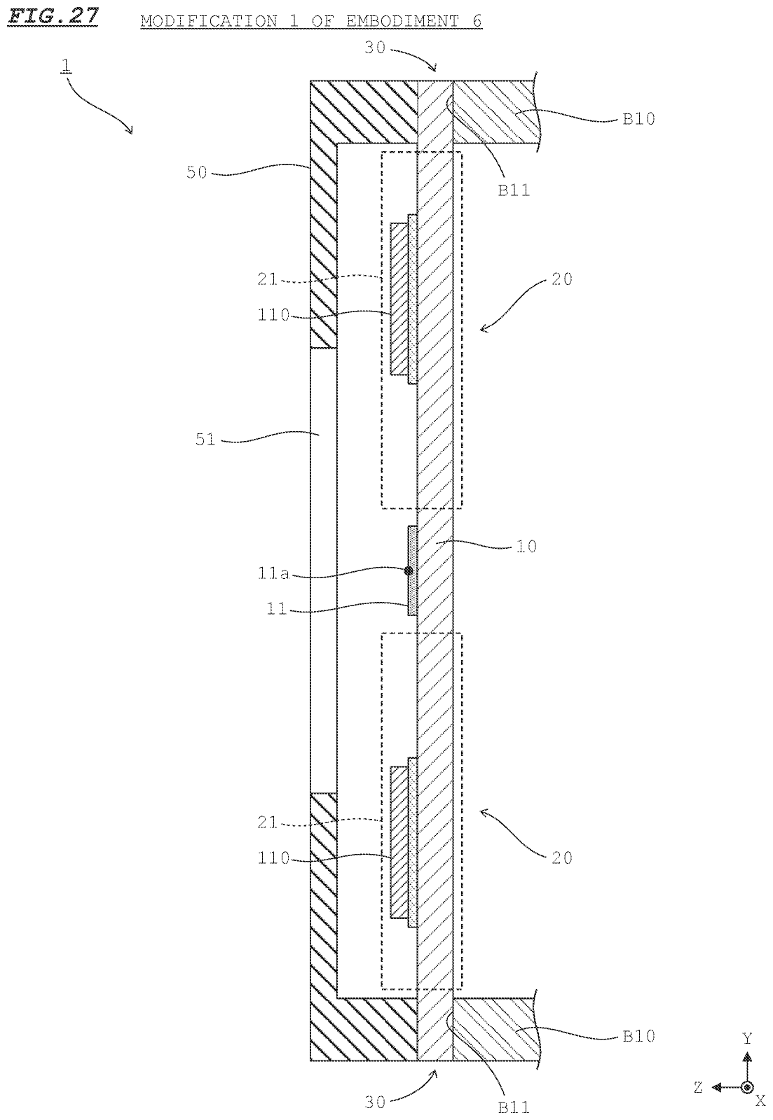

As shown in FIG. 27, the pair of fixing parts 30 are connected to each other by the connection member 50 at a position displaced relative to the rotation axis R10 only in the Z-axis positive direction. The connection member 50 has a hole 51 formed so as to penetrate the connection member 50 in the Z-axis direction. The pair of fixing parts 30 are installed on the installation surfaces B11 of the pair of base members B10. In the present modification as well, the same effects as those of Embodiment 6 are achieved.

### Modification 2 of Embodiment 6

In Embodiment 6 and Modification 1 of Embodiment 6 described above, the pair of fixing parts 30 are connected to each other at the position displaced relative to the rotation axis R10 only in the Z-axis direction. On the other hand, in the present modification, the pair of fixing parts 30 are connected to each other by the connection part 40 at a position displaced relative to the rotation axis R10 only in the X-axis direction.

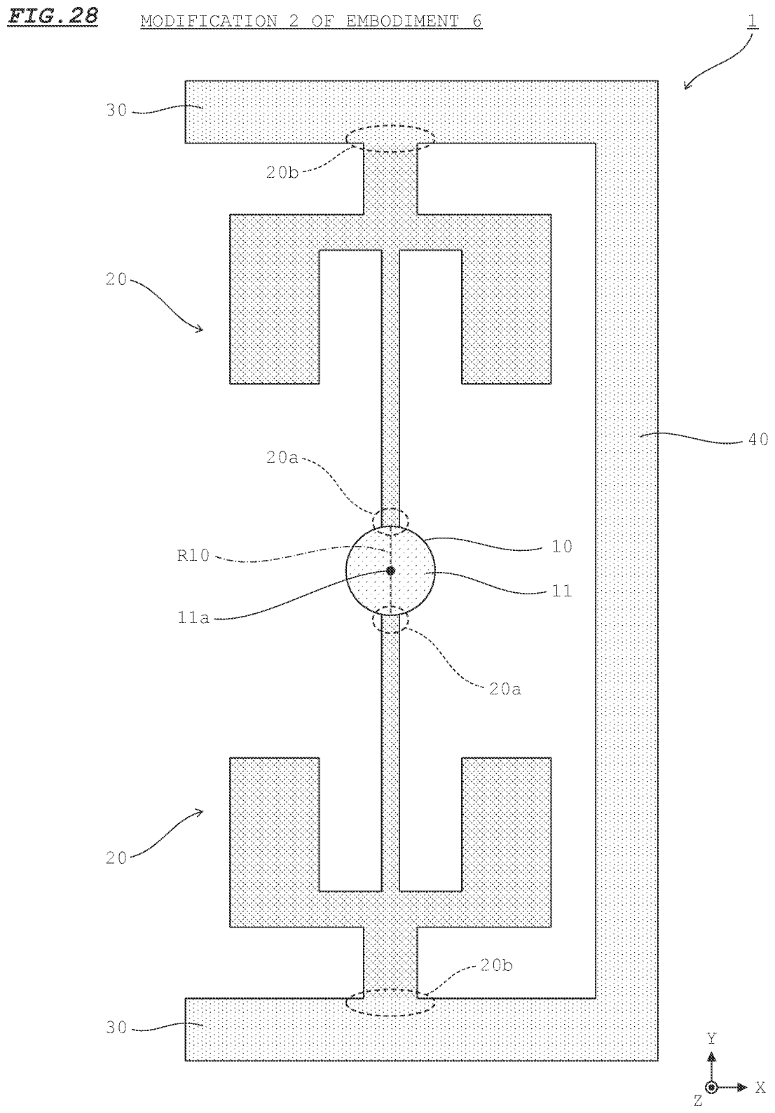

As shown in FIG. 28, the pair of fixing parts 30 are connected to each other by the connection part 40 at a position displaced relative to the rotation axis R10 only in the X-axis positive direction. In the present modification, each fixing part 30 or the connection part 40 is installed on the installation surface B11 of the base member B10. In the present modification as well, the same effects as those of Embodiment 6 are achieved.

### OTHER MODIFICATIONS

In Embodiments 1, 2, and 4 and the modification of Embodiment 4 described above, each fixing part 30 is configured such that the end portion in the Y-axis direction thereof coincides with the outer edge of the piezoelectric drive element 1 in a plan view. However, the present invention is not limited thereto, and a part of the fixing part 30 may extend to the outside of the outer edge of the piezoelectric drive element 1.

In Embodiments 1 and 2 and Modifications 1 and 2 of Embodiment 2 described above, each fixing part 30 is placed in the same range as the gap region G. However, the present invention is not limited thereto, and each fixing part 30 may be placed in a range smaller than the gap region G, within the gap region G. In addition, in Embodiment 3, the modification of Embodiment 3, Embodiment 4, and the modification of Embodiment 4 described above, each fixing part 30 is placed in a range smaller than the gap region G, within the gap region G. However, the present invention is not limited thereto, and each fixing part 30 may be placed in the same range as the gap region G.

Also, in Embodiments 1 and 2 and Modifications 1 and 2 of Embodiment 2 described above, the end portions 20b of the piezoelectric drive parts 20 may be placed so as to surround the movable part 10 as shown in Embodiment 4 and the modification of Embodiment 4 described above. In this case, each gap region G is set as a region that is outside the end portions 20b of the piezoelectric drive element 1 and that is located between the pair of piezoelectric drive parts 20, and the pair of fixing parts 30 are placed in these gap regions G.

In the embodiments and the modifications described above, the number of first drive portions 21 included in one piezoelectric drive part 20 is one, and the number of second drive portions 22 included in one piezoelectric drive part 20 is 0, 1, or 2. However, the number of first drive portions 21 and the number of second drive portions 22 included in one piezoelectric drive part 20 are not limited thereto. The number of first drive portions 21 included in one piezoelectric drive part 20 may be two or more, and the number of second drive portions 22 included in one piezoelectric drive part 20 may be three or more. Furthermore, a piezoelectric drive part may also be provided on each coupling portion 23 in Embodiment 2, Modifications 1 and 2 thereof, Embodiment 3, the modification thereof, Embodiment 4, and the modification thereof.

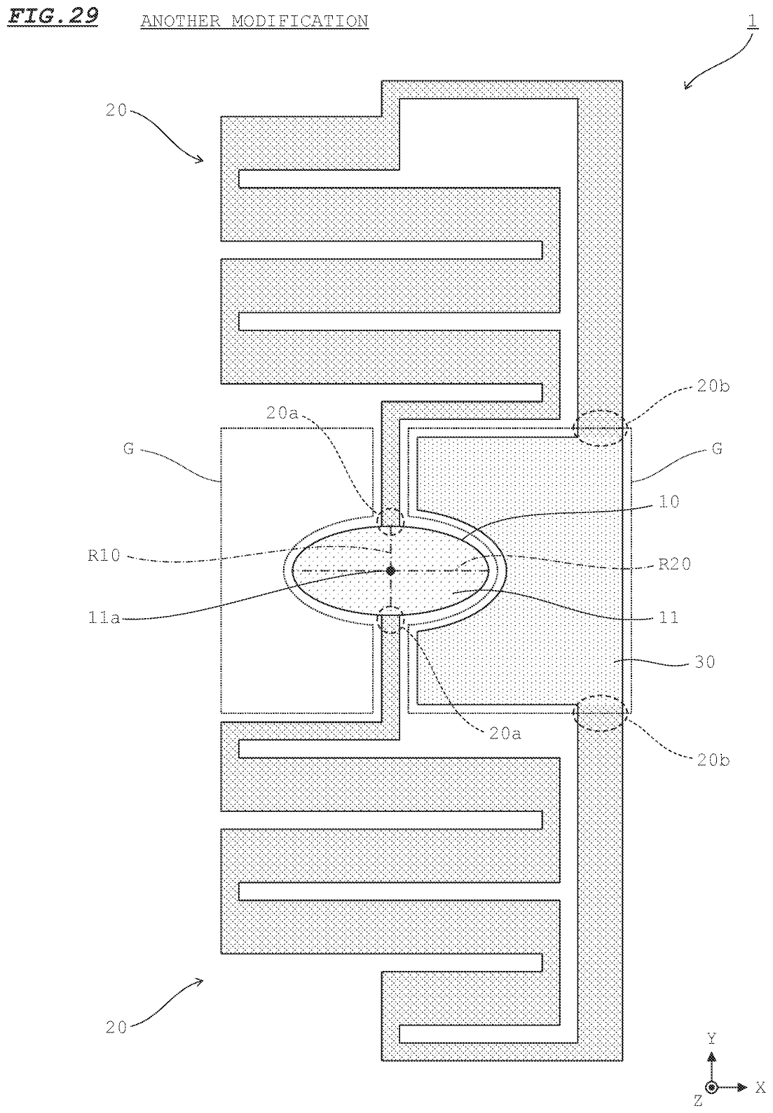

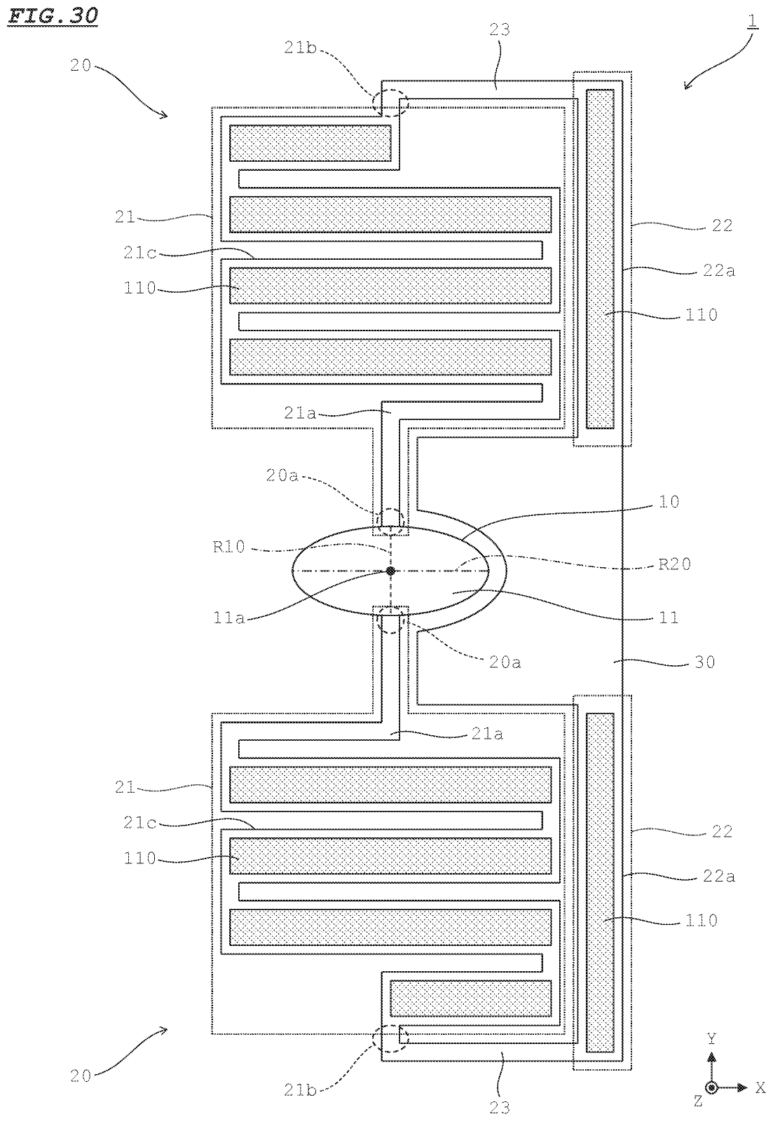

In the embodiments and the modifications described above, the fixing parts 30 are provided in both of the two gap regions G. However, for example, as in a modification shown in FIG. 29 and FIG. 30, the fixing part 30 may be provided in only one of the two gap regions G.

As shown in FIG. 29, in the present modification, as compared to Embodiment 2 shown in FIG. 5, the fixing part 30 is placed in only the gap region G on the X-axis positive side out of the two gap regions G provided with the rotation axis R10 located therebetween. In this configuration, the lower surface of the one fixing part 30 is installed on the installation surface B11 of the base member B10. As shown in FIG. 30, in the present modification, as compared to Embodiment 2 shown in FIG. 5, the second drive portions 22 located on the X-axis negative side in the piezoelectric drive parts 20 are omitted.

In the modification shown in FIG. 29 and FIG. 30 as well, since the one fixing part 30 is placed in the one gap region G, the installation area in the X-Y plane of the piezoelectric drive element 1 can be reduced. In addition, as in Embodiment 2, the second drive portions 22 of the present modification are driven in accordance with the first drive control or the second drive control. Accordingly, the rotational width of the movable part 10 can be widened in accordance with the first drive control, and the movable part 10 can be rotated in the direction of the rotation axis R20 in accordance with the second drive control.

In addition to the above, various modifications can be made as appropriate to the embodiments of the present invention, without departing from the scope of the technological idea defined by the claims.

What is claimed is:

1. A piezoelectric drive element comprising:
a movable part;
a pair of piezoelectric drive parts each connected at one end thereof to the movable part and configured to rotate the movable part about at least a rotation axis; and
a fixing part to which other ends of the piezoelectric drive parts are connected, wherein
the pair of piezoelectric drive parts are aligned in a direction along the rotation axis with the movable part located therebetween,
a width of the movable part is narrower than a width of each of the pair of piezoelectric drive parts in a plan view, and
the fixing part is placed in a gap region that is outside the movable part and that is located between the pair of piezoelectric drive parts in a plan view.

2. The piezoelectric drive element according to claim 1, wherein the fixing part is placed in each of the gap regions on both sides of the rotation axis in a plan view.

3. The piezoelectric drive element according to claim 2, wherein the pair of piezoelectric drive parts each include
a first drive portion connected at one end thereof to the movable part and configured to rotate the movable part about the rotation axis, and
a second drive portion interposed between another end of the first drive portion and the fixing part and configured to drive the other end up and down.

4. The piezoelectric drive element according to claim 3, wherein the one second drive portion of one of the piezoelectric drive parts and the one second drive portion of the other piezoelectric drive part are respectively placed at positions that are point-symmetrical with respect to the movable part.

5. The piezoelectric drive element according to claim 3, wherein, in each piezoelectric drive part, the second drive portion is placed at each of positions that are line-symmetrical with respect to the rotation axis.

6. The piezoelectric drive element according to claim 5, wherein the second drive portion of each piezoelectric drive part on one side with respect to the rotation axis is shared by the pair of piezoelectric drive parts, and the second drive portion of each piezoelectric drive part on another side with respect to the rotation axis is shared by the pair of piezoelectric drive parts.

7. The piezoelectric drive element according to claim 2, wherein the fixing parts placed in the gap regions on both sides are connected to each other.

8. The piezoelectric drive element according to claim 1, wherein the piezoelectric drive part includes a meander-type drive portion.

9. The piezoelectric drive element according to claim 1, wherein the piezoelectric drive part includes a tuning fork-type drive portion.

10. A piezoelectric drive element comprising:
a movable part;
a pair of piezoelectric drive parts each connected at one end thereof to the movable part and configured to rotate the movable part about at least a rotation axis; and
a pair of fixing parts to which other ends of the piezoelectric drive parts are connected, respectively, wherein
the pair of fixing parts are connected to each other at a position displaced relative to the rotation axis only in one direction.

11. The piezoelectric drive element according to claim 10, wherein the piezoelectric drive part includes a meander-type drive portion.

12. The piezoelectric drive element according to claim 10, wherein the piezoelectric drive part includes a tuning fork-type drive portion.
